(19) United States
(12) Patent Application Publication
(10) Pub. No.: US 2025/0187986 A1
(43) Pub. Date: Jun. 12, 2025

(54) 3D/4D ADDITIVE-SUBTRACTIVE MANUFACTURING OF CERAMIC/GLASS COMPONENTS IN 3C PRODUCTS

(71) Applicant: City University of Hong Kong, Hong Kong (HK)

(72) Inventors: Jian LU, Hong Kong (HK); Guo LIU, Hong Kong (HK); Zhifeng ZHOU, Hong Kong (HK); Xiaofeng ZHANG, Guangzhou (CN); Xinya LU, Hefei (CN)

(21) Appl. No.: 18/633,494

(22) Filed: Apr. 11, 2024

(30) Foreign Application Priority Data
Dec. 12, 2023 (CN) 202311704380.2

(51) Int. Cl. C04B 35/524; B28B 1/00; C04B 35/571; G03B 17/56; H05K 5/02

(52) U.S. Cl. CPC C04B 35/524; B28B 1/001; C04B 35/571; G03B 17/561; H05K 5/0243; C04B 2235/3244; C04B 2235/3418; C04B 2235/612; C04B 2235/661; C04B 2235/665; C04B 2235/945; C04B 2235/9661

(57) ABSTRACT

The invention provides a ceramic material or glass material and a manufacturing method thereof. The manufacturing method includes the following steps: preparing a precursor of a ceramic material or a glass material; processing the precursor using a high-energy beam to obtain a processed precursor; and converting the processed precursor into a ceramic material or a glass material. The ceramic material or glass material provided by the present invention is manufactured by this manufacturing method. The present invention uses additive manufacturing technology such as 2D/3D/4D printing combined with subtractive manufacturing technology to manufacture ceramic components or glass components in 3C products. The ceramic material or glass material of the present invention has high resolution and complex shape.

### CROSS-REFERENCE TO RELATED APPLICATIONS

The present application claims priority from a Chinese invention patent application Ser. No. 20/231,1704380.2 filed 12 Dec. 2023, and the disclosures of which are incorporated by reference in their entirety.

### FIELD OF THE INVENTION

The present invention relates to a ceramic material or glass material and its manufacturing method. Specifically, the present invention is related to the field of additive-subtractive manufacturing technical field, relating to ceramic or glass components of electronic devices, and their manufacturing method involving the combined usage of 2D/3D/4D additive manufacturing and subtractive manufacturing.

### BACKGROUND

Ceramic materials play an important role in 3C products. For example, in the 3C industry, ceramic mobile phone back plates are widely used. Ceramic materials not only display excellent performance in electromagnetic signal transmission in 5G networks and wireless charging technology, but also having a smooth appearance and delicate texture due to their unique polished structures, enabling enjoyable visual and tactile experience of users. The fabrication of structural ceramics is limited by the extremely high melting points of candidate materials. Four-dimensional (4D) printing of elastomer-derived ceramics enables a breakthrough in the geometric flexibility of ceramics. However, current ceramic 4D printing systems are limited by time-consuming processing steps, low-resolution deformation mechanisms and structural features. Therefore, there is a need in the field for the development of novel methods and materials using additive manufacturing technologies such as 2D/3D/4D printing combined with subtractive manufacturing technologies to manufacture ceramic components in 3C products.

### SUMMARY OF THE INVENTION

In view of the need above, the present invention provides a ceramic material or glass material and a manufacturing method thereof. Specifically, the purpose of the present invention is to provide a ceramic component or glass component in a 3C product manufactured using additive manufacturing technology such as 2D/3D/4D printing combined with subtractive manufacturing technology and a manufacturing method thereof.

In a first aspect of the present invention, a manufacturing method of a ceramic material or glass material is provided herewith, comprising: preparing a precursor of a ceramic material or glass material; processing the precursor with a high-energy beam to obtain a processed precursor; and transforming the processed precursor into a ceramic material or glass material.

In an embodiment of the first aspect, the precursor comprises a polymer, or a polymer composite material comprising a polymer matrix and a ceramic filler. Preferably, the polymer or polymer matrix is silicone-based or cellulose-based; more preferably, the polymer or polymer matrix is polydimethylsiloxane (PDMS).

In another embodiment, the ceramic filler is in the form of ceramic or glass powders, fibers, whiskers, plates or any combination thereof.

In yet another embodiment, the ceramic filler comprises ZrO₂, AlON, AlN, Al₂O₃, SiC or Si₃N₄, or any combination thereof; more preferably, the ceramic filler comprises ZrO₂, AlON, AlN or Al₂O₃, or any combination thereof.

In other embodiment, the amount of polymer matrix is 10 wt % to 99 wt % and the amount of ceramic fillers is 1 wt % to 90 wt % relative to the total weight of polymer composite material; more preferably, the amount of polymer matrix is 20 wt % to 80 wt % and the amount of ceramic fillers is 20 wt % to 80 wt % relative to the total weight of polymer composite material.

In a specific embodiment of the present invention, a glass material can be prepared by using polymer (especially silicone) as the material of the precursor; and a ceramic material can be prepared by using a polymer matrix and a ceramic filler as the material of the precursor.

In yet another embodiment, the precursor is obtained by additive manufacturing through 2D printing, 3D printing or 4D printing. More specifically, the precursor is a precursor material in the form of liquid, solid powder, solid wire, etc. that is converted into a solid state through additive manufacturing. Further, the additive manufacturing comprises material extrusion, film scraping, material jetting, photopolymerization, powder bed fusion or any combination thereof, which are all conventional material forming processes in the fields of 2D, 3D, and 4D printing technologies.

In a further embodiment, the precursor is obtained by 3D printing or a combination of 3D printing and film scraping. The precursor thus obtained can be further processed for the manufacturing of a stiffener-added mobile phone back plate.

In other embodiment, the high-energy beam is selected from laser beam and/or water beam. The tool utilized to process precursor is not limited to high-energy water beam or laser beam, other processing tools (e.g. electron beam or ion beam) and their combinations may also be used. The subtractive manufacturing (SM) method utilizing high-energy beams is able to enhance manufacturing accuracy.

In another embodiment, the method of processing the precursor includes engraving and/or cutting. More preferably, the processing of the precursor can be adjusted by the type of the high-energy beam, the power of the high-energy beam and the speed of the high-energy beam, or their combinations.

In a further embodiment, the processing of the precursor is by laser engraving and/or laser cutting. Employing such a processing method can achieve high-precision processing of the camera hole on the back plate of the mobile phone, and the inner surface patterning of the back plate.

In another further embodiment, the processing of the precursor is by water cutting. Employing such a processing method can achieve high-precision processing of the camera on the back plate of the mobile phone.

In yet another embodiment, preferably, the above-mentioned method further comprises subjecting the processed precursor to heterogeneous engineering prior to converting into the ceramic material or glass material. More preferably, the heterogeneous engineering comprises subjecting the processed precursor to localized UV/ozone treatment under the cover of a mask. Specifically, the UV/ozone treatment is conducted under room temperature and the time is 10 minutes to 24 hours. Curved or complex-shaped ceramic mobile phone back plates or curved or complex-shaped glass mobile phone back plates can be prepared through heterogeneous engineering of the processed precursors, which is especially suitable for combining with the above-mentioned 4D printing precursor additive manufacturing technology to manufacture curved ceramic or glass phone back plates.

In other embodiment, the converting the processed precursor (or heterogeneous engineered precursor) into a glass material or ceramic material comprises heat processing, mechanical processing or chemical processing, or any combinations thereof, wherein the resulting ceramic material or glass material are high-temperature materials, and through the linear shrinkage during the transformation of the precursor into a glass material or ceramic material, the machining accuracy of the glass material or ceramic material can be improved. More preferably, the linear shrinkage is controlled within a range of 1% to 70%.

In a further embodiment, the processed precursor (or heterogeneous-engineered precursor) is partially converted into glass material or ceramic material via localized heat processing. More specifically, the processed precursor (or heterogeneous-engineered precursor) is partially converted on the upper or lower part. Through the localized heat processing, the partially heat-processed parts become a rigid glass or ceramic material, while the remaining parts without heat processing remain to be flexible, which enables the manufacturing of a hybrid rigid-flexible ceramic or glass material for foldable phone back plates.

In another embodiment, the processed precursor is subjected to heat processing in inert gas or vacuum conditions to undergo primary ceramization; and further subjecting to heat processing in air to undergo secondary ceramization. As the components and colours of the primary ceramized and secondary ceramized materials are different, printable and colour-tunable ceramic materials can therefore be obtained.

In yet another embodiment, the ceramic material and glass material has a high resolution and complex shape; more preferably, the resolution (machining accuracy) of the glass material and ceramic material is as high as 6 micrometers.

Preferably, the above-mentioned glass material or ceramic material can be used for 3C electronic device components.

Furthermore, preferably the processing the precursor is by laser engraving, which adopts a positive engraving and/or negative engraving to form artistic and/or decorative three-dimensional structural features on the surface of the precursor. Using this processing method, the final product can be used as ceramic art pieces and/or decorations, or as ceramic components in 3C electronic devices with artistic and/or decorative properties. It should be noted that this processing method can be combined with the above-mentioned precursor processing method to produce a ceramic mobile phone back plate with structures such as camera holes and artistic and/or decorative properties.

In another embodiment, the above method further comprises partially receramizing the prepared ceramic material to obtain heterogeneous ceramics, preferably through localized heat processing. More preferably, the localized heat processing is conducted on the ceramic material under the cover of a mask for subsequent partial receramizing. Laser cutting can be used to obtain the heat processing mask. The localized heat processing is performed under inert gas or vacuum conditions, and the temperature is preferably at least 800° C.; more preferably in the range of 1100° C. to 1500° C. The obtained heterogeneous ceramics are suitable as ceramic artworks and/or decorations, or as ceramic components in 3C electronic devices with artistic and/or decorative properties.

In some specific embodiments of the present invention, the prepared ceramic material or glass material is a ceramic mobile phone back plate or a glass mobile phone back plate. Among them, when laser processing is used to process the precursor, precision processing of the camera hole of the mobile phone back plate and the inner surface texture of the mobile phone back plate can be achieved, wherein the color of the border of the digital files for laser machining the ceramic mobile phone back plate or the glass mobile phone back plate can be designed to gradually become lighter to achieve a 2.5D arc edge. Among them, curved ceramic mobile phone back plates or curved glass mobile phone back plates can be prepared through heterogeneous engineering of processed precursors. Among them, localized heat processing can be used to prepare soft/rigid hybrid ceramic materials and soft/rigid hybrid glass materials to manufacture foldable ceramic mobile phone back plates or foldable glass mobile phone back plates respectively. Among them, the ceramic mobile phone back plate with reinforced parts can be manufactured through the combination of the scraping film and 3D printing technology or through 3D printing technology. The precise processing of the camera hole on the back plate of the mobile phone can be achieved through the four methods of laser cutting or engraving methods on precursor involved in the present invention. In addition, the precise processing of the camera hole on the back plate of the mobile phone can also be achieved by processing the precursor by water cutting.

In another embodiment, the ceramic material obtained is an anti-fingerprint polished ceramic plate, which can be used as a ceramic mobile phone back plate, or other components of 3C electronic devices. More preferably, the anti-fingerprint polished ceramic plate has a ZrO₂—SiOC nanocrystalline amorphous dual-phase structure.

In some embodiments, the prepared ceramic materials are ceramic art pieces and/or decorations, or ceramic components in 3C electronic devices with artistic and/or decorative properties. Preferably, the method of producing ceramic art pieces and/or decorations, and ceramic components in artistic and/or decorative 3C electronic devices comprises using laser engraving to process the precursor, and the laser engraving adopts positive engraving and/or negative engraving methods to form artistic and/or decorative three-dimensional structural features on the surface of the precursor. Preferably, ceramic art pieces and/or ornaments, and ceramic components in artistic and/or decorative 3C electronic devices are obtained from heterogeneous ceramics, which are obtained by partial receramization of the material. More preferably, the partial re-ceramization of the ceramic material is achieved by subjecting the ceramic material to localized heat processing.

In an embodiment, the ceramic material or glass material obtained are units of glass or ceramic microelectromechanical systems in 3C electronic devices. Preferably, the ceramic material or glass material obtained are used as resonant strain sensors or gear systems of ceramic or glass microelectromechanical systems in 3C electronic devices.

A second aspect of the present invention provides a glass or ceramic component of a 3C electronic device manufactured according to the method as discussed above.

In an embodiment of the second aspect of the present invention, the glass or ceramic component is a ceramic or glass mobile phone back plate. More preferably, the glass or ceramic component is (i) a curved ceramic or glass mobile phone back plate; (ii) a foldable ceramic or glass mobile phone back plate; or (iii) a stiffener-added ceramic or glass mobile phone back plate. When the precursor is processed through laser, precise processing of the camera hole and internal surface patterning of the mobile phone back plate can be achieved, wherein the color of the border of the ceramic mobile phone back plate or the glass mobile phone back plate can be designed to gradually become lighter to achieve a 2.5D arc edge. A curved ceramic or glass mobile phone pack plate can be manufactured through 4D printing by using a precursor subjected to heterogeneous engineering. A hybrid soft/rigid ceramic precursor/ceramic material or hybrid soft/rigid glass precursor/glass material to manufacture foldable ceramic or glass mobile phone back plates respectively. The precise processing of the camera hole on the back plate of the mobile phone can be achieved through the four methods of laser cutting or engraving methods on precursor involved in the present invention. In addition, the precise processing of the camera hole on the back plate of the mobile phone can also be achieved by processing the precursor by water cutting.

Preferably, the ceramic material is an anti-fingerprint polished ceramic plate, which can be applied as a ceramic mobile phone back plate or other components in 3C electronic devices. More preferably, the anti-fingerprint polished ceramic plate has a ZrO₂—SiOC crystalline amorphous dual-phase structure.

In other embodiments, the prepared ceramic materials are ceramic art pieces and/or decorations, or ceramic components in 3C electronic devices with artistic and/or decorative properties. Preferably, the method of producing ceramic art pieces and/or decorations, and ceramic components in artistic and/or decorative 3C electronic devices comprises using laser engraving to process the precursor, and the laser engraving adopts positive engraving and/or negative engraving methods to form artistic and/or decorative three-dimensional structural features on the surface of the precursor. Preferably, ceramic art pieces and/or ornaments, and ceramic components in artistic and/or decorative 3C electronic devices are obtained from heterogeneous ceramics, which are obtained by partial receramization of the material. More preferably, the partial re-ceramization of the ceramic material is achieved by subjecting the ceramic material to localized heat processing.

In yet an embodiment, the ceramic material or glass material obtained are units of glass or ceramic microelectromechanical systems in 3C electronic devices. Preferably, the ceramic material or glass material obtained are used as resonant strain sensors or gear systems of ceramic or glass microelectromechanical systems in 3C electronic devices.

Provided herewith in the present invention is a ceramic or glass material and its manufacturing methods through 3D/4D additive-subtractive manufacturing technologies, including the production of precursors, the laser-or water-engraving and/or cutting processing of the precursor, heterogeneous engineering of the precursor (optional), ceramization or partial ceramization of the precursor (optional) and partial receramization of ceramic materials (optional), to obtain ceramic or glass parts applicable in 3C electronic devices. The ceramic or glass materials in the present invention have high resolution and complex shapes, which can broaden the application of ceramic materials in 3C electronic devices, including ceramic mobile phone back plates, foldable 3C devices, colour-tunable ceramic materials, ceramic artworks and decorations, ceramic MEMS and anti-fingerprint ceramic plates.

### BRIEF DESCRIPTION OF THE DRAWINGS

FIG. 1 shows a schematic diagram of precursor laser engraving (PLE) and precursor laser cutting (PLC) method. The precursor materials are machined by laser, and then the laser-machined precursors are transformed into high-temperature materials.

FIG. 2 illustrates the precise adjustment of the engraved depth of the precursor material by laser power and laser speed. The depth resolutions along the X and Y axes are 50 μm.

FIGS. 3A to 3E are photographs of high-resolution and large-scale ceramic gear systems with hybrid additive-subtractive manufacturing. FIG. 3A shows laser-engraved ceramic precursor gear systems with the diameter of 54 mm. FIGS. 3B, 3C, 3D and 3E show individual ceramic gears with diameters of 5.6 mm (FIG. 3B), 2.8 mm (FIG. 3C), 1.4 mm (FIG. 3D) and 0.7 mm (FIG. 3E), obtained through the PLE method.

FIG. 4 shows the 3D optical profile of laser-engraved ceramic groove in an embodiment of the present invention.

FIG. 5 shows a large-scale (over 10 cm in length) and flat ceramic plate obtained in an embodiment of the present invention.

FIG. 6 shows photographs of ceramics of an embodiment of a present invention, transformed from laser-engraved precursors, with uniform linear shrinkage (30%) and good structural retention. The ceramics exhibit metallic luster after polishing.

FIGS. 7A to 7C shows the shows TEM results of the printed ceramic and glass materials. FIG. 7A shows that nanoparticles with primary sizes of 20-50 nm were uniformly distributed in the resulting ceramics. FIGS. 7B and 7C are high-resolution TEM images and selected-area electron diffraction (SAED) results (inset), showing that when induction heat treated at 1300° C. the ceramic and glass precursors transformed to nanonanocrystalline-amorphous dual-phase (NCADP) ceramics (as shown in FIG. 7B) and amorphous glass (as shown in FIG. 7C) respectively.

FIGS. 8A to 8E show the NCADP structure of printed ZrO₂—SiOC ceramic lattices. FIG. 8A is the TEM image; FIG. 8B is the high-resolution TEM image; FIG. 8C is the SAED result; FIG. 8D is the EDS mapping analysis and FIG. 8E is the EDS line analysis of the printed ZrO₂—SiOC ceramic lattices.

FIGS. 9A to 9E show the NCADP structure of printed AlON—SiOC ceramic lattices. FIG. 9A is the TEM image; FIG. 9B is the high-resolution TEM image; FIG. 9C is the SAED result; FIG. 9D is the EDS mapping analysis and FIG. 9E is the EDS line analysis of the printed AlON—SiOC ceramic lattices.

FIGS. 10A and 10B shows the design for laser machining of the mobile phone back plate. In FIG. 10A, the depth of the color represents the depth of the engraving, where the darker the color, the deeper the engraving. In FIG. 10B, it can be observed that the color of the border is designed as gradually lighter to achieve a 2.5D arc edge.

FIGS. 11A and 11B illustrates heterogeneous engineering by localized UV/ozone treatment. FIG. 11A shows the design of the mask for the mobile phone back plate. FIG. 11B shows the precursor material with the mask for localized UV/ozone exposure.

FIG. 12A shows a large-scale flat ceramic mobile phone back plate, and FIG. 12B shows a large-scale curved ceramic mobile phone back plate, both with high-resolution structural features obtained from PLC/PLE.

FIG. 13 shows illustration of soft/rigid hybrid ceramic precursor/ceramic material mobile phone back plate. Hybrid 3D/4D printing materials with integrated soft ceramic precursors and rigid ceramics resulting from the localized ceramization of precursor materials or multi-material printing/assembly can facilitate the development of foldable ceramic mobile phone back plates.

FIG. 14 shows a ceramic cellphone back plate with stiffeners manufactured with film scraping and 3D printing technique.

FIG. 15A and 15B show Method 1 in hole machining on ceramic precursor materials. FIG. 15A is a schematic diagram of Method 1 and the cross-section of the hole. FIG. 15B is the microscopic viewing of a 5 mm and 1 mm diameter hole.

FIG. 16A and 16B show Method 2 in hole machining on ceramic precursor materials. FIG. 16A is a schematic diagram of Method 2 and the cross-section of the hole. FIG. 16B is the microscopic viewing of a 5 mm and 1 mm diameter hole.

FIG. 17A and 17B show Method 3 in hole machining on ceramic precursor materials. FIG. 17A is a schematic diagram of Method 3 and the cross-section of the hole. FIG. 17B is the microscopic viewing of a 5 mm and 1 mm diameter hole.

FIG. 18A and 18B show Method 4 in hole machining on ceramic precursor materials. FIG. 18A is a schematic diagram of Method 4 and the cross-section of the hole. FIG. 18B is the microscopic viewing of a 5 mm and 1 mm diameter hole.

FIG. 19 is a comparison of the above four methods in hole machining on ceramic precursors.

FIG. 20 shows the schematics of precursor water cutting (PWC) and precursor water engraving (PWE) method. The precursor materials are machined by water, and then the water-machined precursors are transformed into high-temperature materials.

FIG. 21 shows holes machined by PWC method on glass precursors.

FIG. 22 shows ceramic precursor planetary gear systems machined by PWC method.

FIG. 23 shows running ceramic precursor planetary gear systems machined by PWC method.

FIG. 24 shows printable color-tunable ceramics developed in the present invention.

FIG. 25 shows an illustration of the application in the art and decoration manufacturing of ceramic components in 3C electronic products.

FIGS. 26A and 26C compares large-scale ceramic flat plates with delicate positive engraving of the mural character in “Flying Apsaras” in Dunhuang Murals with the original mural engravings. FIG. 26A is the original image of the mural characters; FIG. 26B shows the ceramic precursor and FIG. 26C shows the ceramic material.

FIG. 27 shows large-scale ceramic precursor flat plates with delicate positive engraving of the “Mona Lisa”.

FIGS. 28A to 28C shows large-scale ceramic flat plates with delicate negative engraving of Chinese traditional calligraphy characters in “Preface to the Poems Composed at the Orchid Pavilion” by Wang Xizhi in running script with the original calligraphy texts. FIG. 28A shows the original image of the calligraphy texts, FIG. 28B shows the ceramic material and FIG. 28C shows the 3D optical profile.

FIG. 29 shows the fabrication of heterogeneous ceramics via the localized re-ceramization of ceramic materials.

FIG. 30 illustrates the application in MEMbviuhjybgftr5cxz S manufacturing of ceramic components in 3C electronic products.

FIGS. 31A to 31D show laser-engraved MEMS structure. FIG. 31A shows the structural design of the MEMS structure; FIG. 31B is a digital image of the ceramic precursor MEMS structure obtained using the PLE method; FIG. 31C shows the optical profile of the ceramic precursor MEMS structure with a resolution as high as 80 μm; and FIG. 31D shows the 3D optical profile of the ceramic MEMS structure obtained using the PLE method.

FIG. 32 shows that a typical ceramic microelectromechanical systems (MEMS) resonant strain sensor (over 10 cm in length, 2812 pairs of electrodes, the depth and width of the tuning forks were about 20 μm and 60 μm, respectively) was built, with the design based on a double-ended tuning fork (DETF) topology.

FIGS. 33A to 33D shows planetary gear systems machined by PLC method. FIG. 33A shows the ceramic precursor; FIG. 33B shows the ceramic materials derived from the precursor; FIG. 33C shows the assembled planetary gear systems; and FIG. 33D is the SEM image.

FIG. 34 shows running ceramic planetary gear systems machined by PLC method.

FIG. 35 demonstrates the anti-fingerprint property of the polished ceramic plate in the present invention.

### DETAILED DESCRIPTION

In order to have a clearer understanding of the technical features, purposes and beneficial effects of the present invention, the technical solutions of the present invention are described in detail below, but this should not be understood as limiting the implementable scope of the present invention.

In preferred embodiments of the present invention, the ceramic or glass material provided in the present invention is manufactured through: (i) preparing the precursor of the ceramic or glass material; (ii) processing the precursor through high-energy beam to form a high-resolution and complex-shaped processed precursor; (iii) transforming the processed precursor into ceramic or glass material with high resolution and complex shapes.

The precursor comprises a polymer or a polymer composite material comprising a polymer matrix and ceramic fillers. Further, the ceramic filler is in the form of ceramic or glass powders, fibers, whiskers, plates or any combination thereof; preferably the ceramic filler is in the form of powder with a particle diameter of 1 nm to 100 μm, more preferably 10 nm to 10 μm. The ceramic filler selected from ZrO₂, AlON, AlN, Al₂O₃, SiC or Si₃N₄, or any combination thereof, more preferably ZrO₂, AlON, AlN, Al₂O₃ or any combination thereof. The polymer or polymer matrix is silicone-or cellulose-based, more preferably the polymer or polymer matrix is polydimethylsiloxane (PDMS).\

The amount of polymer matrix is 10 wt % to 99 wt % and the amount of ceramic fillers is 1 wt % to 90 wt % relative to the total weight of polymer composite material; more preferably, the amount of polymer matrix is 20 wt % to 80 wt % and the amount of ceramic fillers is 20 wt % to 80 wt % relative to the total weight of polymer composite material.

Glass material can be obtained when the precursor is a polymer (especially silicone); and ceramic material can be obtained when the precursor is a polymer composite material comprising polymer matrix and ceramic fillers.

The precursor is obtained by additive manufacturing through 2D printing, 3D printing or 4D printing. More specifically, the precursor is a precursor material in the form of liquid, solid powder, solid wire, etc. that is converted into a solid state through additive manufacturing. Further, the additive manufacturing comprises material extrusion, film scraping, material jetting, photopolymerization, powder bed fusion or any combination thereof, which are all conventional material forming processes in the fields of 2D, 3D, and 4D printing technologies.

More specifically, the film scraping technology shapes the precursor material in the ink state into a thin film structure on the substrate through a scraper, and then solidifies it into a solid precursor, which is also an additive manufacturing method. The material extrusion technology converts the solid wire state into a thin film structure. The precursor material is continuously formed into a certain shape through a certain-shaped nozzle under the action of heating, melting and extrusion, and then solidified into a solid precursor. Material extrusion technology, such as ink direct writing, ink direct writing technology converts the precursor in ink form into threads, extruded by air pressure or a screw, and through the program-controlled displacement of the nozzle, stacked layer by layer into a 3D structure, and then solidified into a solid precursor. Material jetting technology is one of the 3D printing technologies, using a print head corresponding to a paper inkjet head to deposit droplets of liquid precursor material to the desired location, and a print head generally has dozens to hundreds of nozzles for material deposition. Photopolymerization technology is a process that utilizes UV or visible light to trigger the rapid transformation of chemically reactive liquid substances into solid substances, thereby converting liquid precursor materials into solid precursors. Powder bed fusion technology is an additive manufacturing technology, designed to be flexible and highly efficient in resource utilization. It involves laying a thin layer of powder material on the substrate, irradiating and heating the entire powder layer with electron beams or lasers. The above processes are repeated alternately to stack and form a precursor with the desired shape.

The method of processing the precursor includes engraving and/or cutting. More preferably, the processing of the precursor can be adjusted by the type of the high-energy beam, the power of the high-energy beam and the speed of the high-energy beam, or their combinations.

In an embodiment of the present invention, the precursor is obtained through 3D printing or film scraping, wherein the high-energy beam is selected from laser or water beam, etc. The tool utilized to process precursor is not limited to high-energy water beam or laser beam, other processing tools (e.g. electron beam or ion beam) and their combinations may also be used. The subtractive manufacturing (SM) method utilizing high-energy beams is able to enhance manufacturing accuracy.

the converting the processed precursor (or heterogeneous engineered precursor) into a glass material or ceramic material comprises heat processing, mechanical processing or chemical processing, or any combinations thereof, wherein the resulting ceramic material or glass material are high-temperature materials, and through controlling the linear shrinkage within a range of 1% to 70% during the transformation of the precursor into a glass material or ceramic material, the machining accuracy of the glass material or ceramic material can be improved.

In one embodiment, the transforming the processed precursor into a ceramic or glass material is by heat processing.

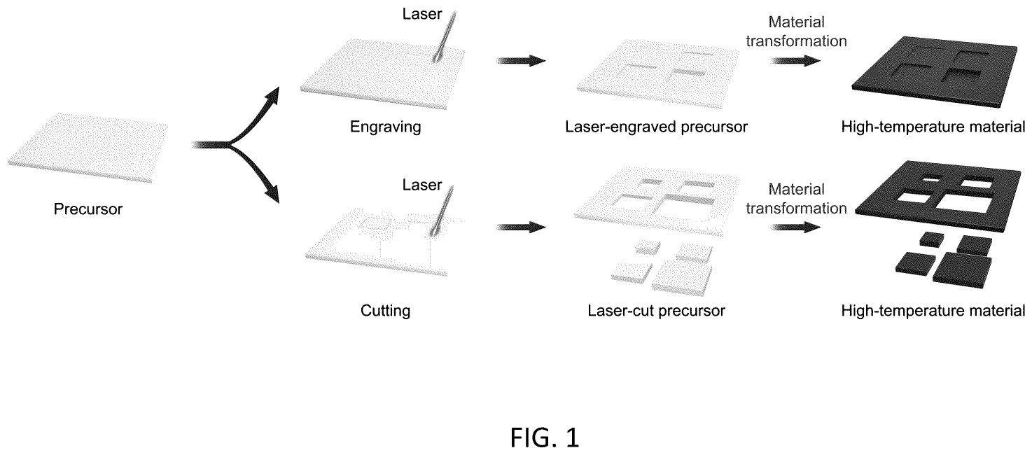

Accordingly, in a specific embodiment of the present invention as shown in FIG. 1, the precursor is obtained by 3D printing or film scraping the above-mentioned meticulously designed precursor material (the material forms an ink system). The precursor is then engraved and/or cut by subtractive manufacturing (SM) technology using high-energy beams (such as laser beams) to obtain the processed precursor, wherein specific laser scanning power and speed are adopted to obtain the best results; and a high-resolution additive-subtractive material manufacturing (ASM) system is formed at the same time. The processed precursor is then transformed into high-temperature structural materials (or high-temperature materials). For example, the processed precursor can be heat-processed to achieve the transformation, and the high-temperature material obtained is the ceramic material or glass material of the present invention.

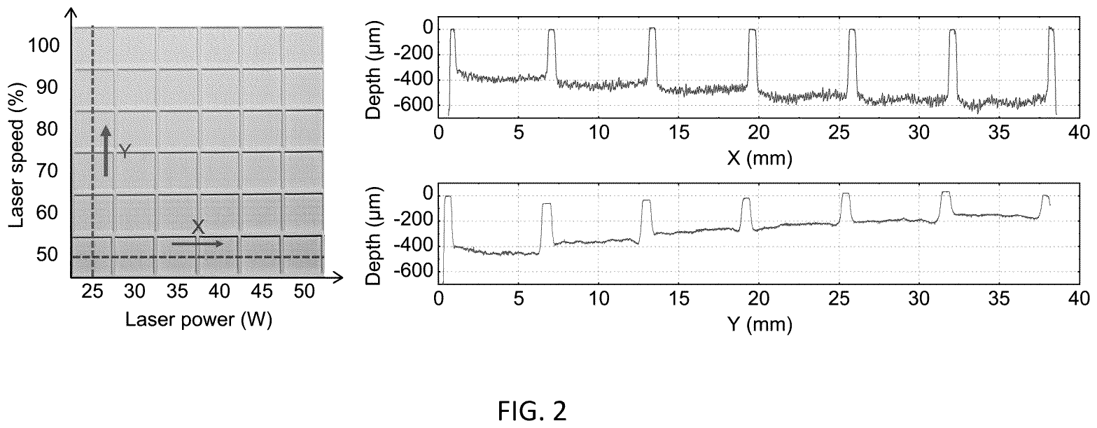

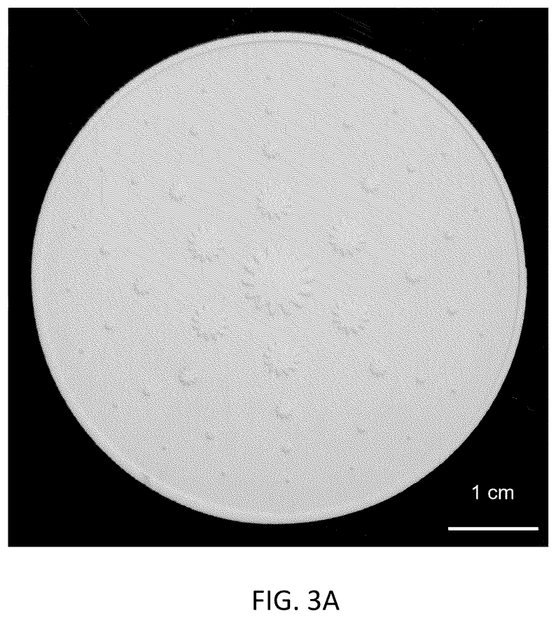

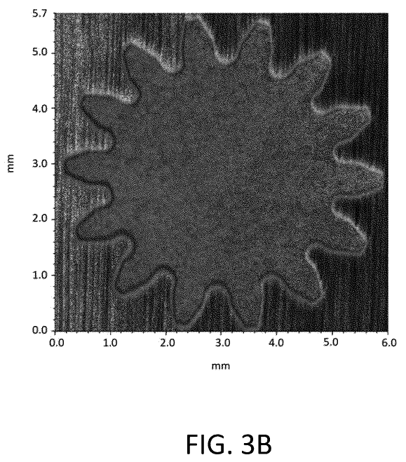

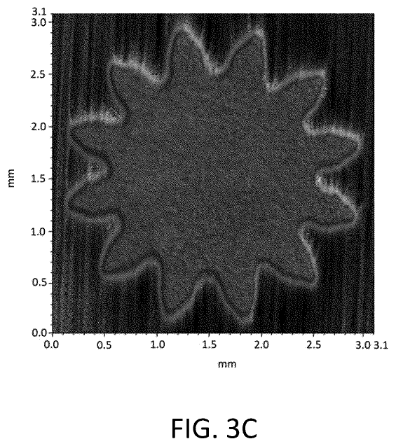

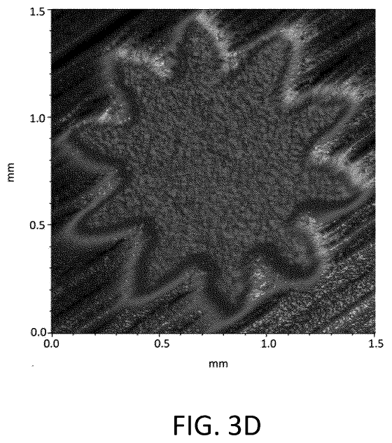

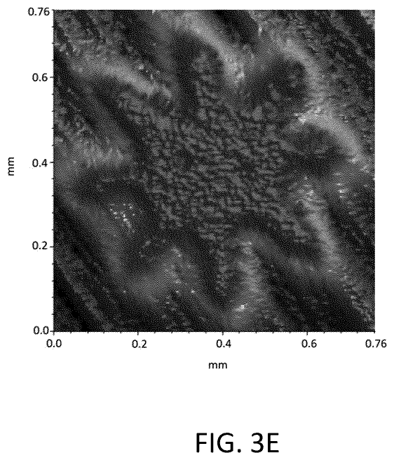

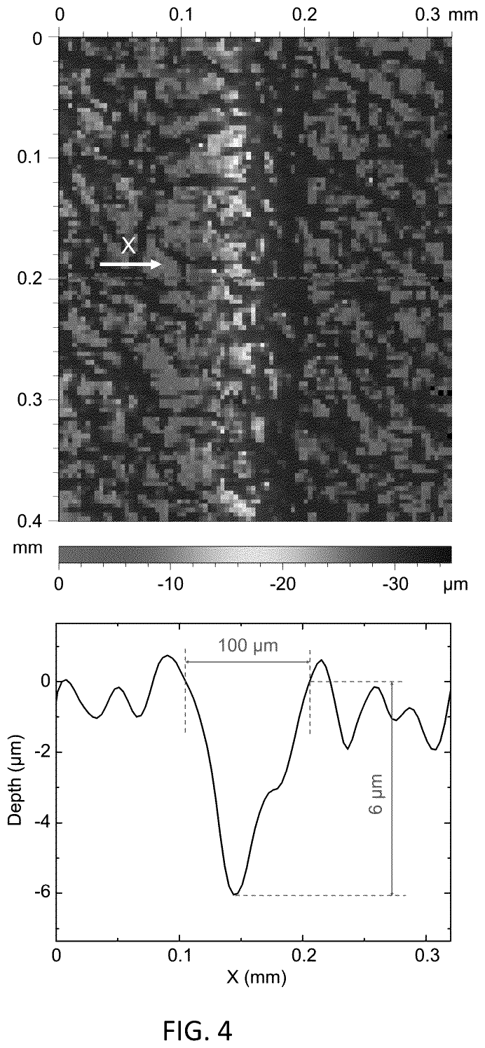

In another embodiment, different laser scanning powers and speeds are used to process the precursor, and then mapping models of different laser scanning powers and speeds are established. FIG. 2 shows the precise adjustment of the engraving depth of the precursor by laser power and laser speed, with a depth resolution of 50 μm along the X-and Y-axes. As is shown in FIG. 2, by increasing the laser scanning power (power=25-50 W) and reducing the laser scanning speed, deeper engraving depths can be generated, which can be precisely adjusted in intervals of approximately 50 μm. After converting the processed precursor into a ceramic material (ceramization), the final ceramic material prepared by laser processing has a maximum resolution of 6 μm (as shown in FIGS. 3 and 4), which is more than 30 times higher than that of the direct ink writing (DIW) technology. FIG. 3 shows a high-resolution and large-scale ceramic gear system manufactured by a combination of additive and subtractive manufacturing techniques in a specific embodiment of the present invention, wherein FIG. 3A shows a laser-engraved gear system manufactured from the ceramic precursor with a diameter of 54 mm. FIGS. 3B to 3E show the single ceramic gears with diameters of 5.6 mm, 2.8 mm, 1.4 mm and 0.7 mm respectively, all obtained by precursor laser engraving (PLE). FIG. 4 shows the 3D optical profile of the ceramic grooves produced by laser engraving.

The novel precursor material system and PLE/PLC methods adopted in the present invention not only allows the processing technology of the high-temperature material to be able to achieve high resolutions, but also reduces the cost and is environmentally friendly.

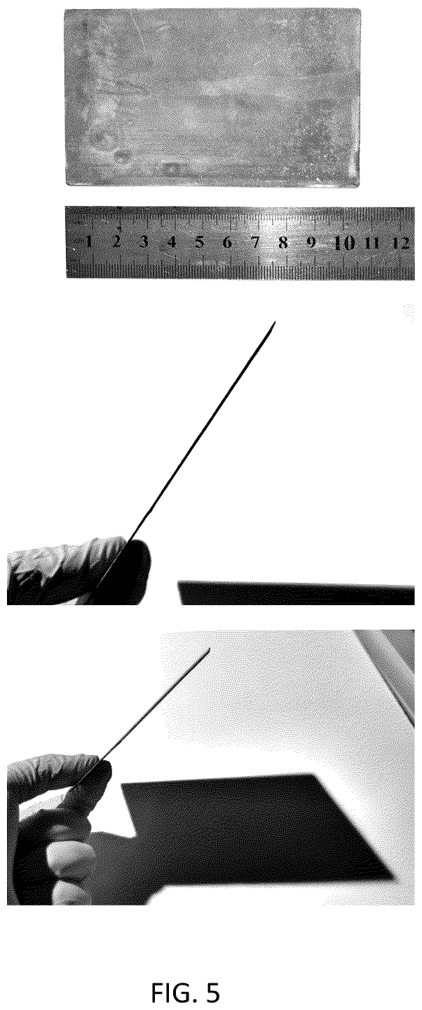

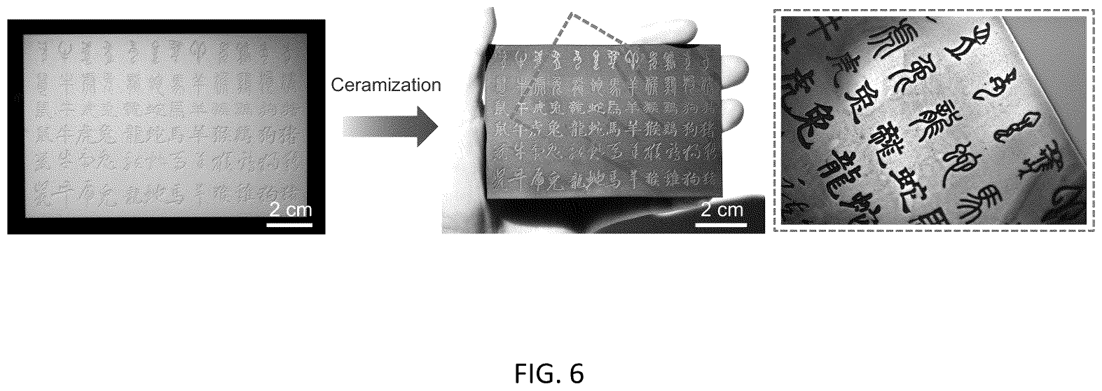

In an embodiment, after the processed precursor is converted into a ceramic material or a glass material, the 3D structure of the ceramic material remains flat and demonstrates uniform linear shrinkage, thereby maintaining the overall shape and local features (as shown in FIGS. 5 and 6). FIG. 5 shows a large-sized (length exceeding 10 cm) flat ceramic plate obtained in a specific embodiment of the present invention. FIG. 6 shows a specific embodiment of the present invention using laser engraving to process the precursor, and then transforms (ceramizes) it into a ceramic material with uniform linear shrinkage (30%) and good structural retention. The ceramic material appears after polishing demonstrates metallic luster.

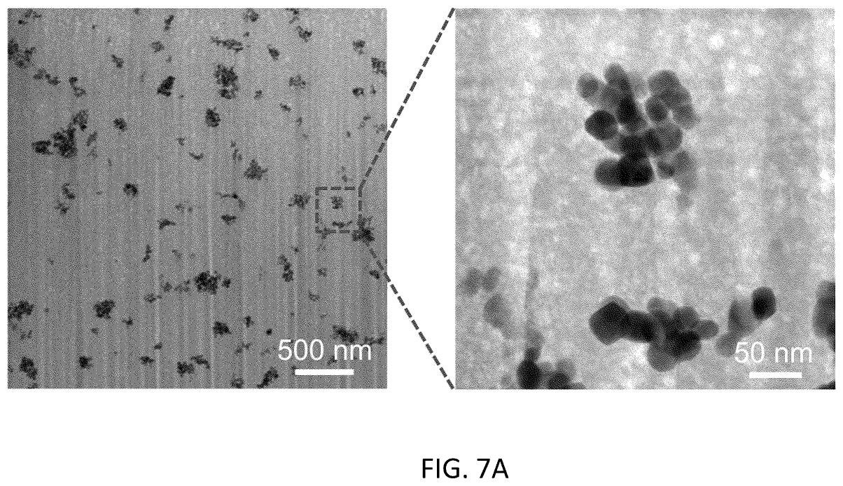

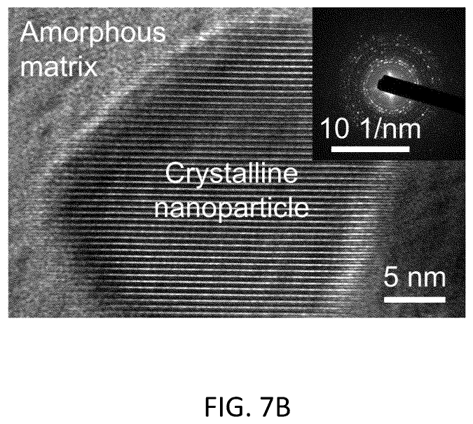

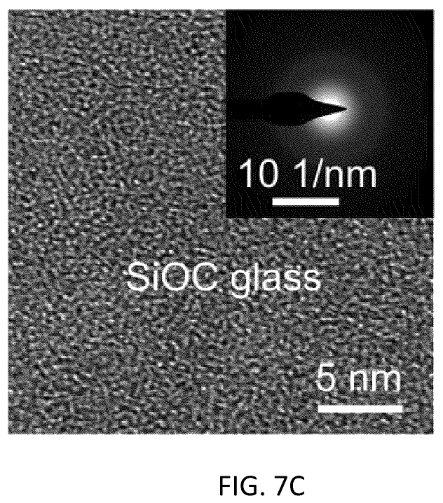

In an embodiment, after the processed precursor is subjected to induction heat treatment at 1300° C., it is converted into ZrO₂—SiOC nanocrystalline-amorphous dual-phase (NCADP) ceramics or amorphous SiOC glass (as shown in FIG. 7). The average composition of the obtained ceramic is SiO_{0.74}C_{0.43}Zr_{0.18}, and the average composition of the obtained glass is SiO_{0.59}C_{0.25}. FIG. 7 shows TEM results of ceramic and glass materials in an embodiment of the present invention. Among them, FIG. 7A is a TEM image. It can be seen that nanoparticles with an original size of 20-50 nm are evenly distributed in the resulting ceramic. FIGS. 7B and 7C are high-resolution TEM images and selected area electron diffraction (SAED) results (insets). It can be observed that after induction heat treatment at 1300° C., the ceramic and glass precursors are transformed into NCADP ceramics (FIG. 7B) and amorphous glass (FIG. 7C) respectively.

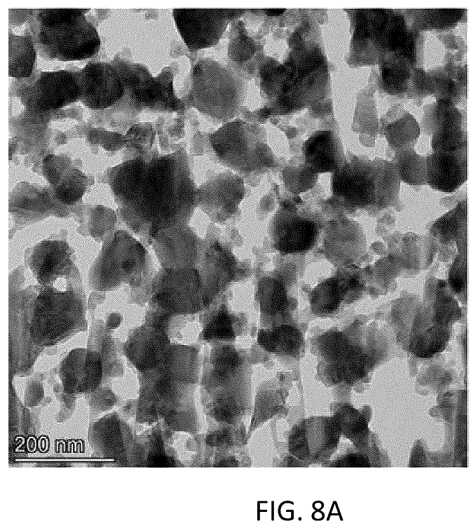

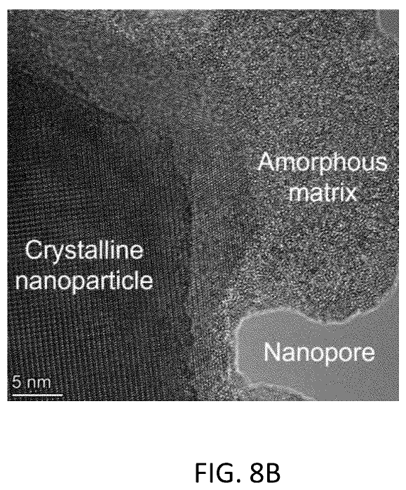

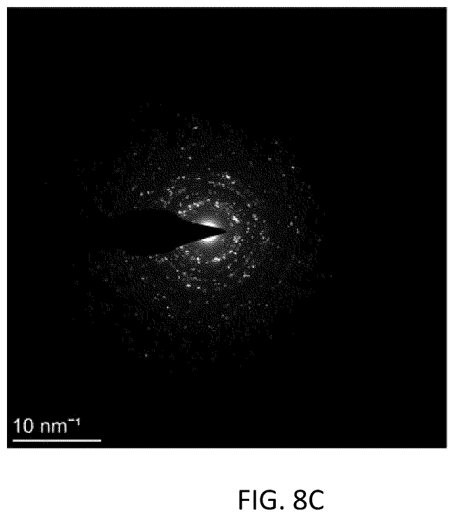

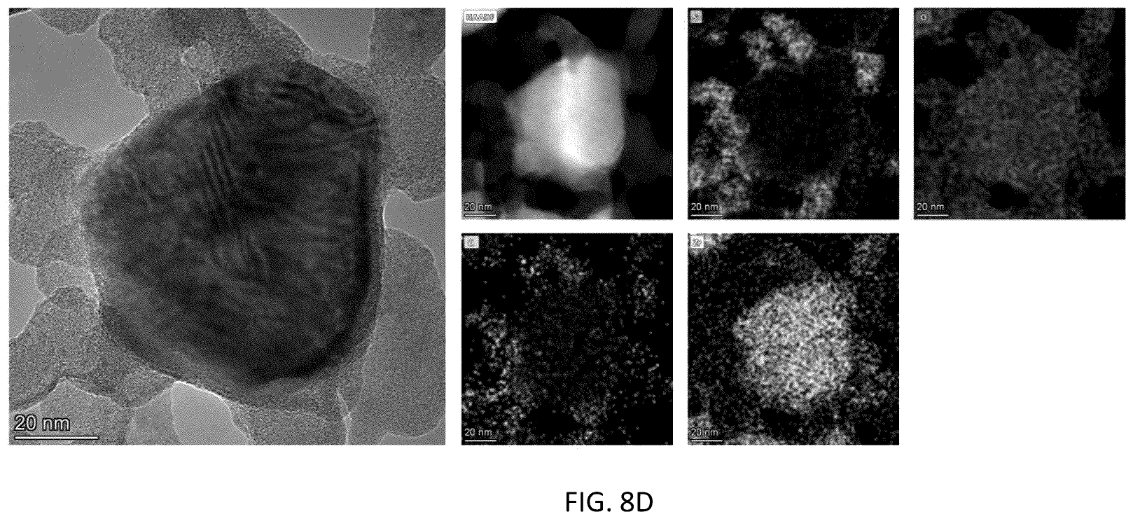

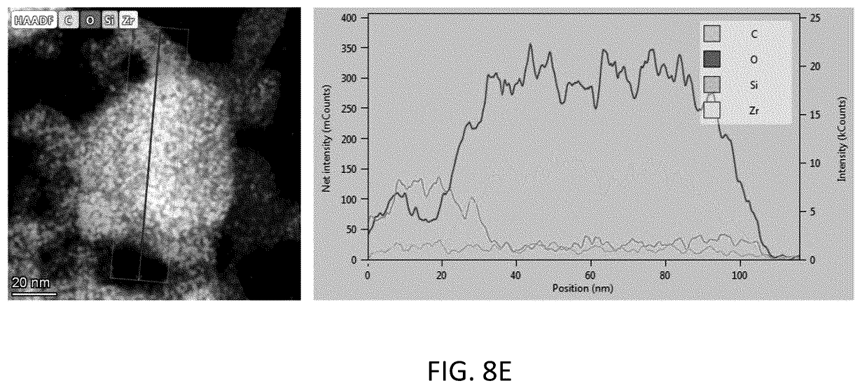

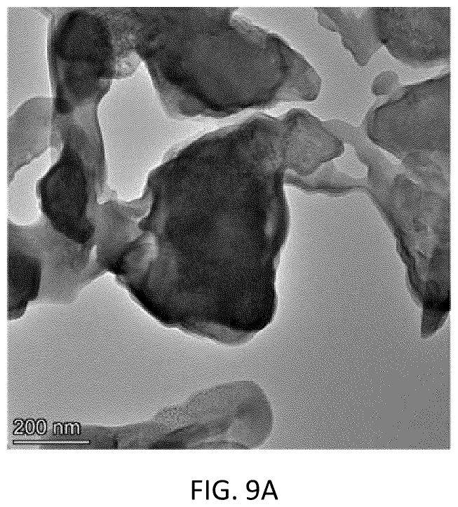

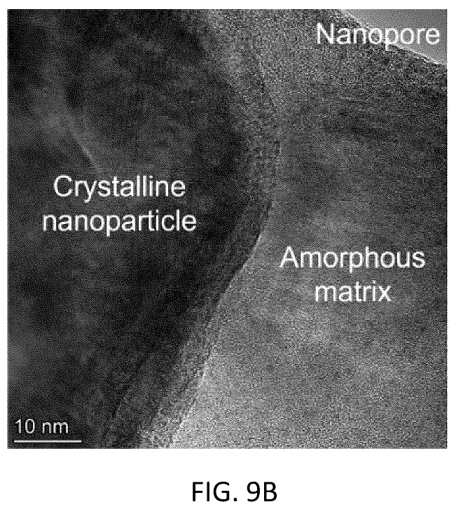

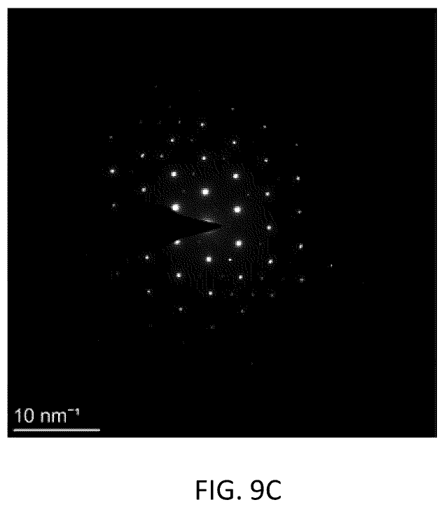

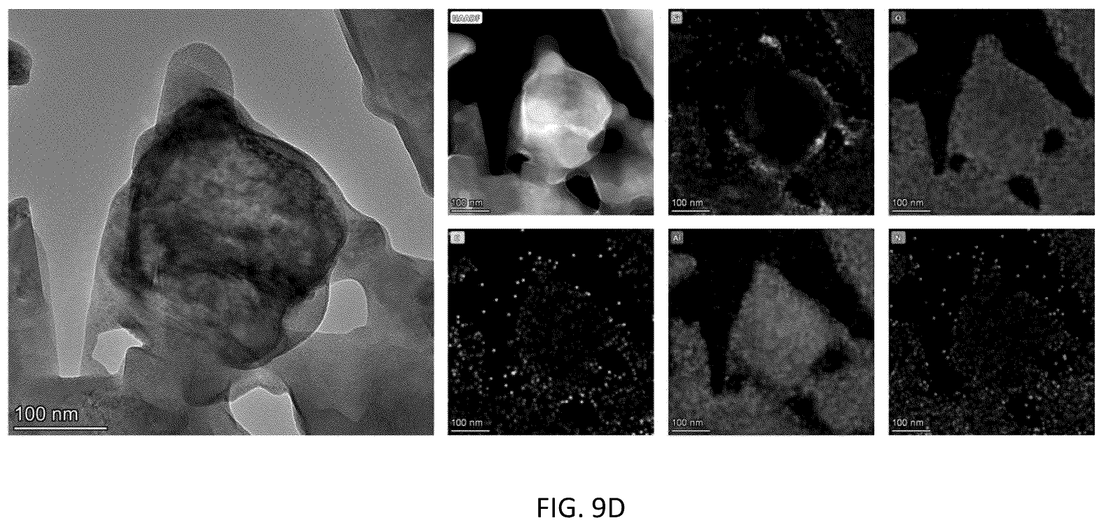

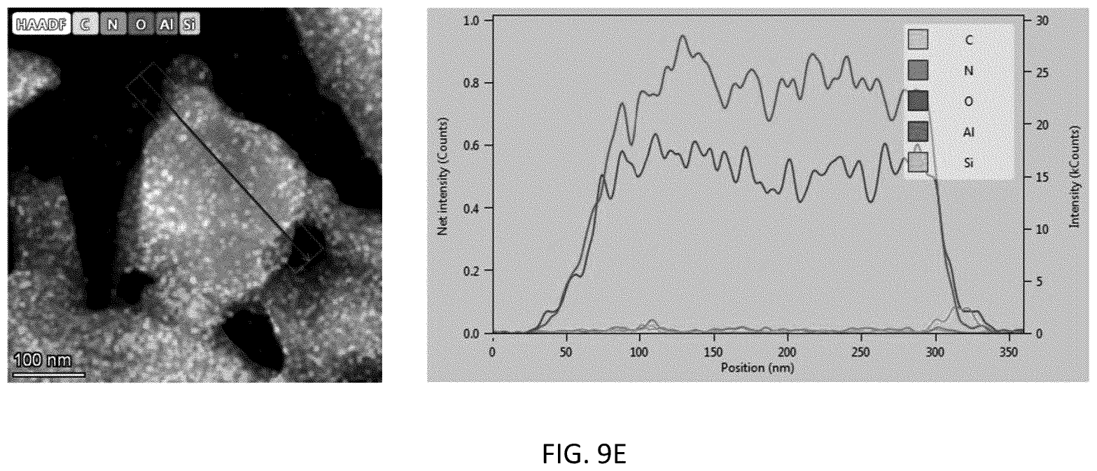

In an embodiment, the structure of the obtained ceramic material is a ZrO₂—SiOC nanocrystal-amorphous dual-phase structure with nanopores or an AlON—SiOC nanocrystal-amorphous dual-phase structure with nanopores (as shown in FIGS. 8 and 9). FIG. 8 shows the ZrO₂—SiOC ceramic lattice NCADP structure of the ceramic material obtained in a specific embodiment of the present invention. FIG. 8A is the TEM image; FIG. 8B is the high-resolution TEM image; FIG. 8C is the SAED result; FIG. 8D is the EDS mapping analysis and FIG. 8E is the EDS line analysis of the printed ZrO₂—SiOC ceramic lattices. FIG. 9 shows the AlON—SiOC ceramic lattice NCADP structure of the ceramic material obtained in a specific embodiment of the present invention. FIG. 9A is the TEM image; FIG. 9B is the high-resolution TEM image; FIG. 9C is the SAED result; FIG. 9D is the EDS mapping analysis and FIG. 9E is the EDS line analysis of the printed AlON—SiOC ceramic lattices.

The additive/subtractive manufacturing technology in the present invention achieves a synergistic effect between the resolution and scalability of ceramic and glass materials.

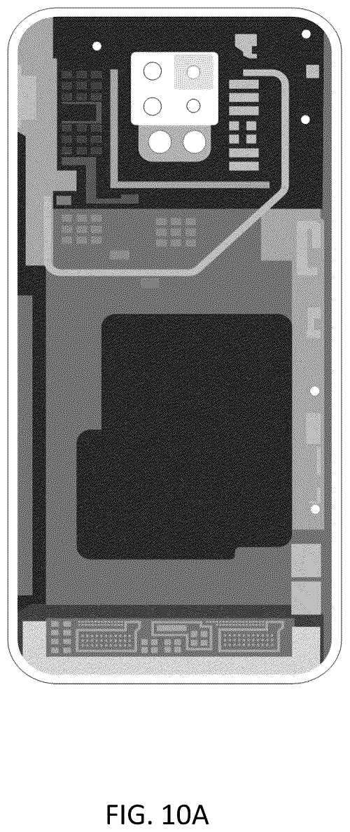

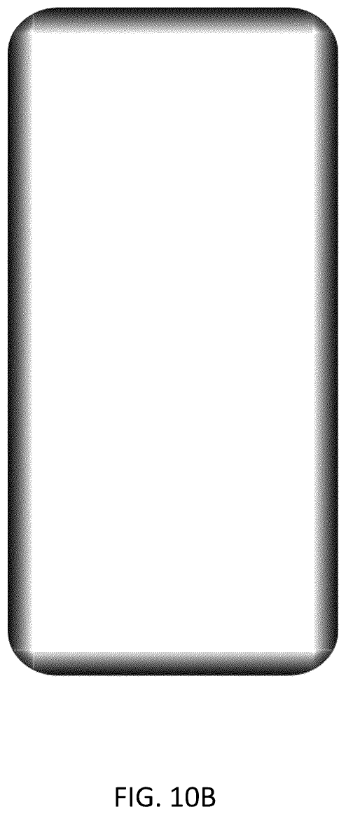

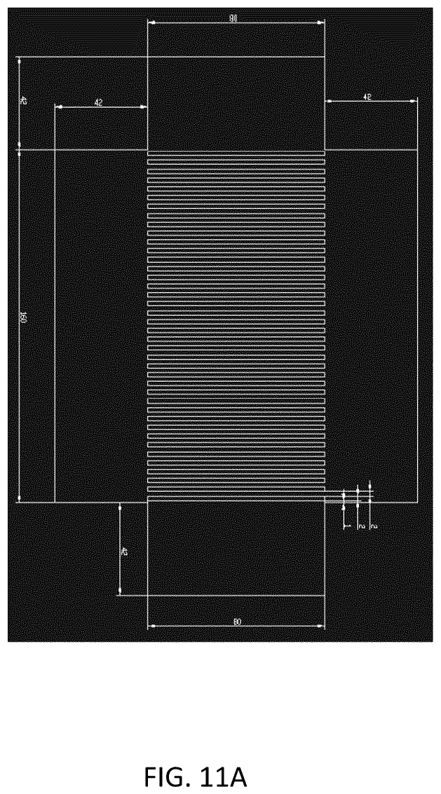

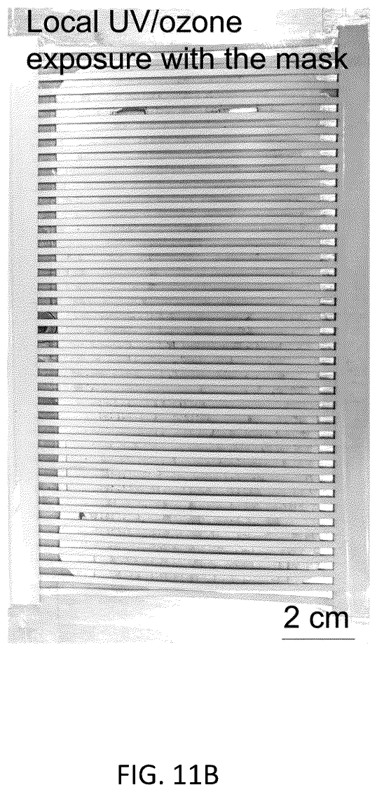

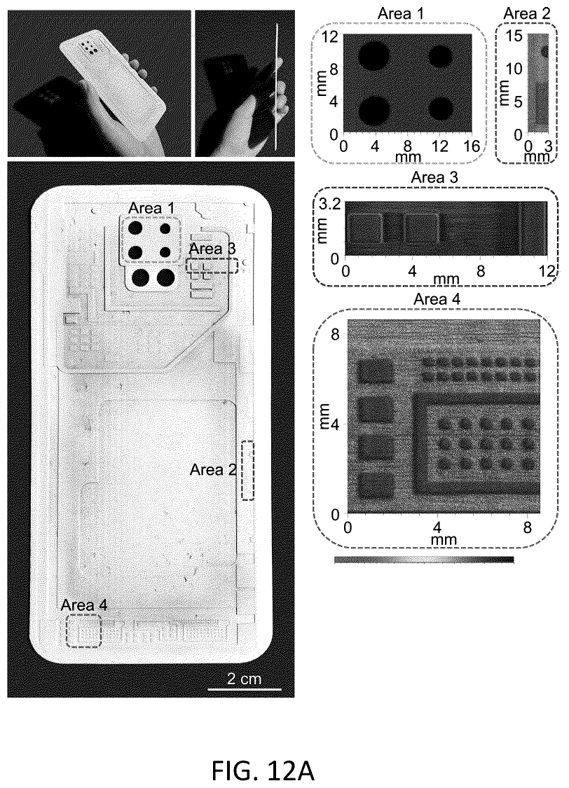

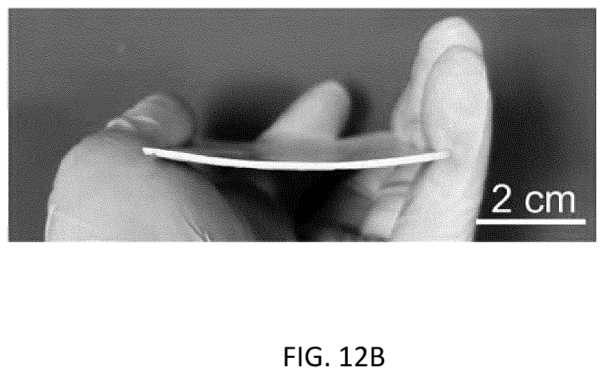

Based on the above-mentioned ASM system, the ceramic material or glass material produced is a ceramic mobile phone back plate or a glass mobile phone back plate. FIG. 10 shows the laser processing design of the back plate of a mobile phone in a specific embodiment of the present invention. The depth of the color in FIG. 10A represents the depth of the engraving. The darker the color, the deeper the engraving. The color of the frame in FIG. 10B is designed to gradually become lighter to achieve a 2.5D arc edge. In this embodiment, heterogeneous engineering is performed on the laser-processed precursor. The heterogeneous engineering is to perform localized UV/ozone treatment on the processed precursor under the cover of a mask. Specifically, the UV/ozone treatment is conducted under room temperature and in a time period of 10 minutes to 24 hours (preferably 30 minutes 24 hours). FIG. 11 shows a heterogeneous engineering design diagram for localized UV/oxygen treatment of processed precursors. FIG. 11A shows the mask design of the mobile phone back plate; FIG. 11B shows the local exposure of the precursor to UV/oxygen under the mask. Curved or complex-shaped ceramic mobile phone back plates can be prepared through the heterogeneous engineering. Some thin film areas are formed on the surface of the precursor of the ceramic material, and the thickness of the film is adjusted by changing the treatment time of the ultraviolet (UV)/ozone system. For example: after treatment for 8 hours, the film thickness is 33 microns; after treatment for 16 hours, the film thickness is 38 microns. In this embodiment, the heterogeneously engineered precursor is then heat treated under inert gas or vacuum conditions. The thermal expansion and contraction behaviors of the 2D UV/oxygen film formed by exposure to the UV/oxygen environment and the parts of the precursor that are not exposed to the UV/oxygen environment are different. This heterogeneity leads to the morphological transformation of the precursor structure. FIG. 12 shows a large flat ceramic mobile phone backplane and a curved ceramic mobile phone backplane with high-resolution PLC/PLE processing structural features. It is observed that the above-mentioned PLC and PLE processing methods help to accurately process the camera hole of the ceramic mobile phone backplate and the inner surface texture of the ceramic mobile phone backplate with high cost-efficiency (as shown in FIG. 12A). The above-mentioned heterogeneous engineering can build a 3D ceramic mobile phone back plate with a curved surface (as shown in FIG. 12B).

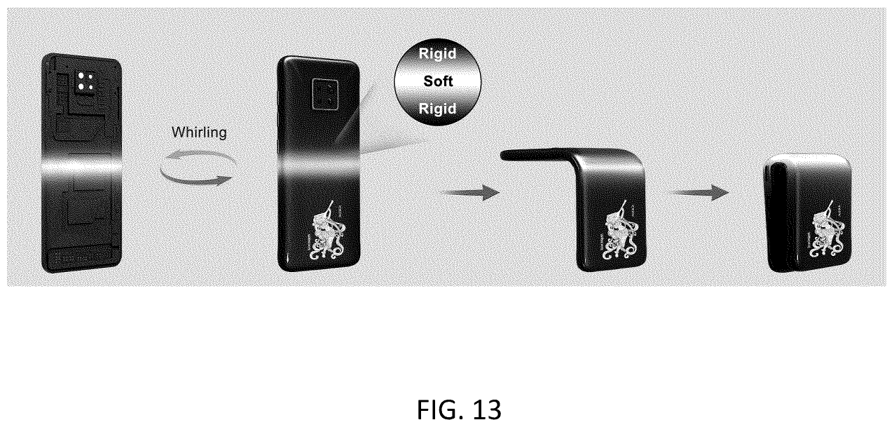

The processed precursor (or heterogeneous-engineered precursor) is partially converted into glass material or ceramic material via localized heat processing. More specifically, the processed precursor (or heterogeneous-engineered precursor) is partially converted on the upper or lower part. Through the localized heat processing, the partially heat-processed parts become a rigid glass or ceramic material, while the remaining parts without heat processing remain to be flexible, which enables the manufacturing of a hybrid rigid-flexible ceramic or glass material for foldable phone back plates. A foldable ceramic mobile phone back plate (as shown in FIG. 13) prepared by localized heat processing (ie, local ceramization) of the precursor is provided herewith. FIG. 13 shows a foldable ceramic mobile phone back plate made of soft/rigid hybrid ceramic precursor/ceramic material. Foldable ceramic mobile phone back platesls can also be obtained through multi-material printing/assembly of soft/rigid hybrid ceramic precursors.

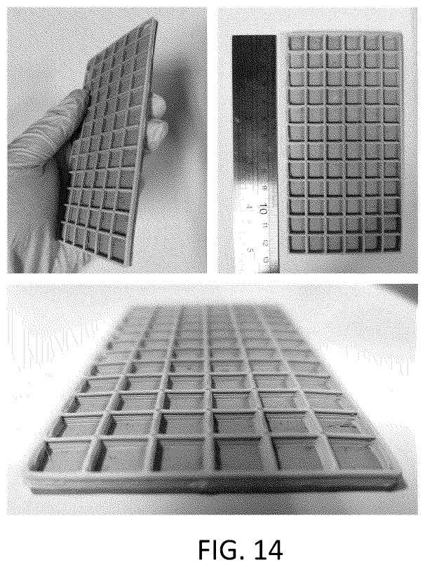

A ceramic mobile phone back plate with stiffener added is obtained by film scraping and 3D printing techniques (as shown in FIG. 14). FIG. 14 shows the stiffener-added ceramic mobile phone back plate as obtained by film scraping and 3D printing techniques.

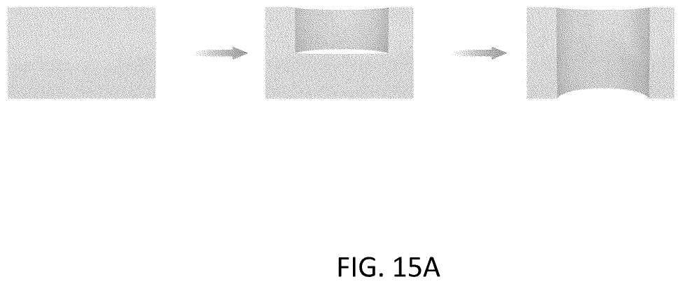

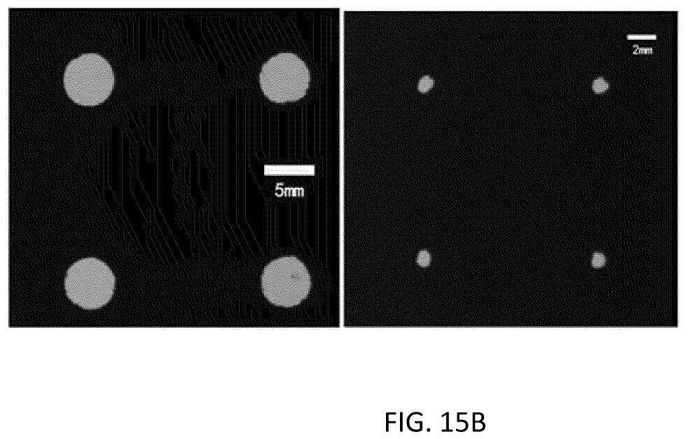

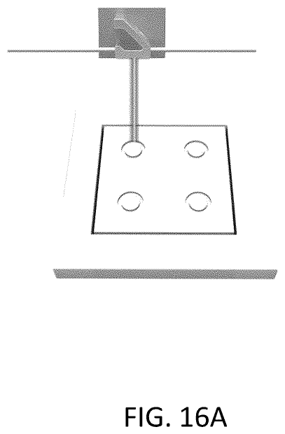

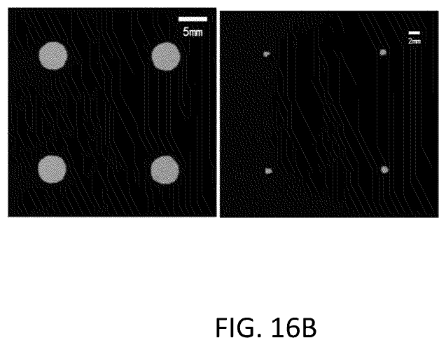

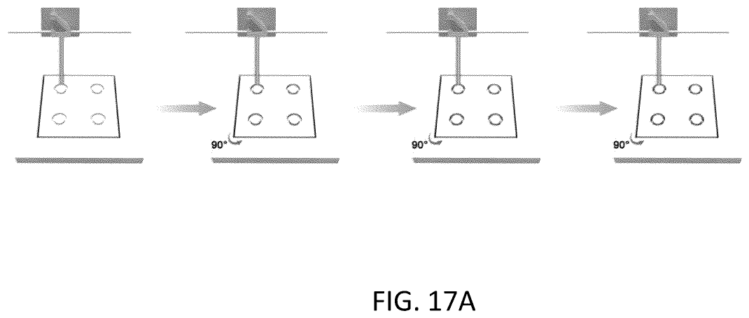

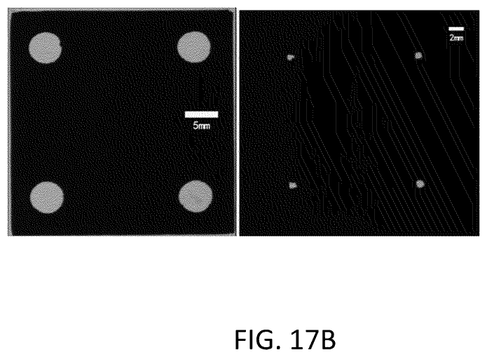

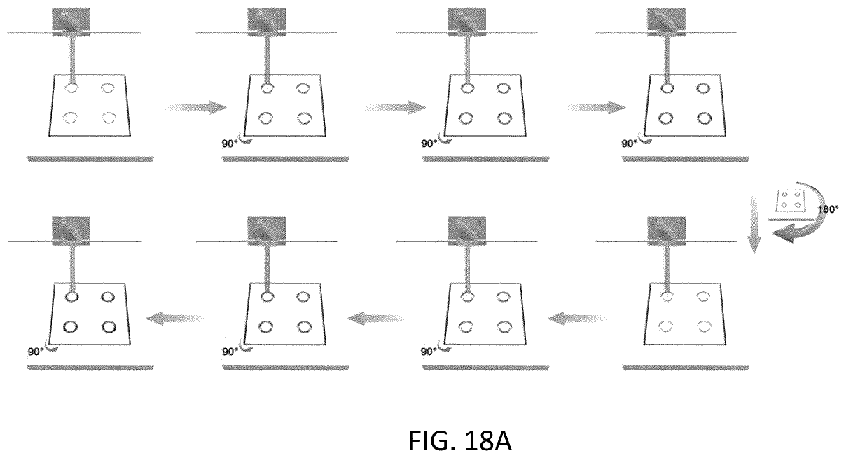

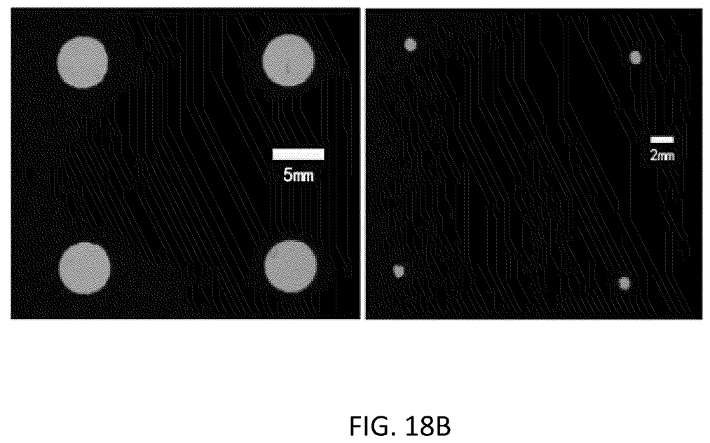

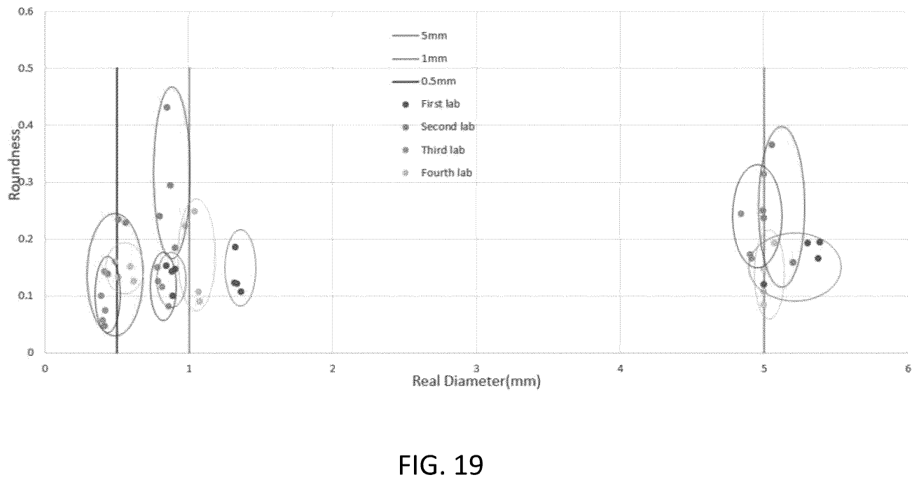

The precise processing of camera holes is enhanced by the aforementioned PLC and PLE methods. FIGS. 15-18 demonstrates four methods of hole processing on the ceramic precursor. FIG. 15A is a schematic diagram of Method 1 and the cross-section of the hole. FIG. 15B is the microscopic viewing of a 5 mm and 1 mm diameter hole. FIG. 16A is a schematic diagram of Method 2 and the cross-section of the hole. FIG. 16B is the microscopic viewing of a 5 mm and 1 mm diameter hole. FIG. 17A is a schematic diagram of Method 3 and the cross-section of the hole. FIG. 17B is the microscopic viewing of a 5 mm and 1 mm diameter hole FIG. 18A is a schematic diagram of Method 4 and the cross-section of the hole. FIG. 18B is the microscopic viewing of a 5 mm and 1 mm diameter hole. FIG. 19 is a comparison of the four methods of hole processing. As observed, the point on Method 4 is relatively nearer to the control line, and the roundness value of the three different diameters are relatively close to zero. Therefore, it is concluded that Method 4 is a better method compared to the other three.

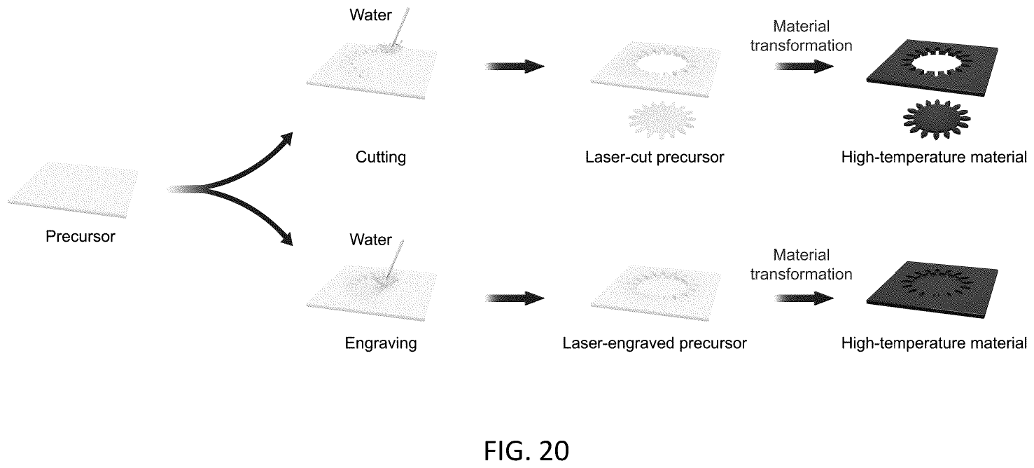

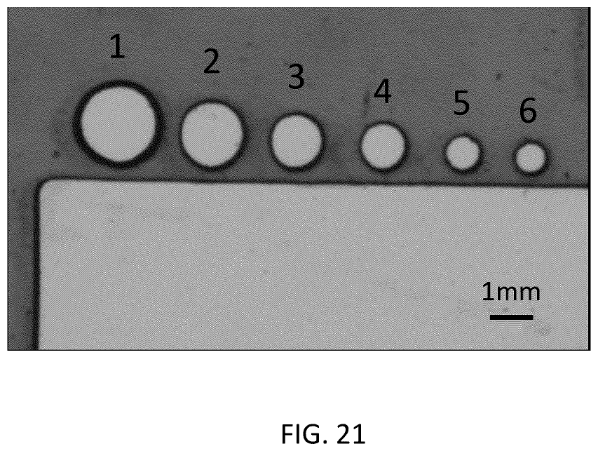

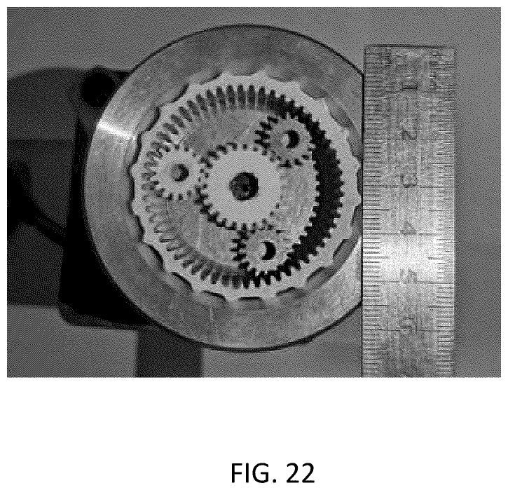

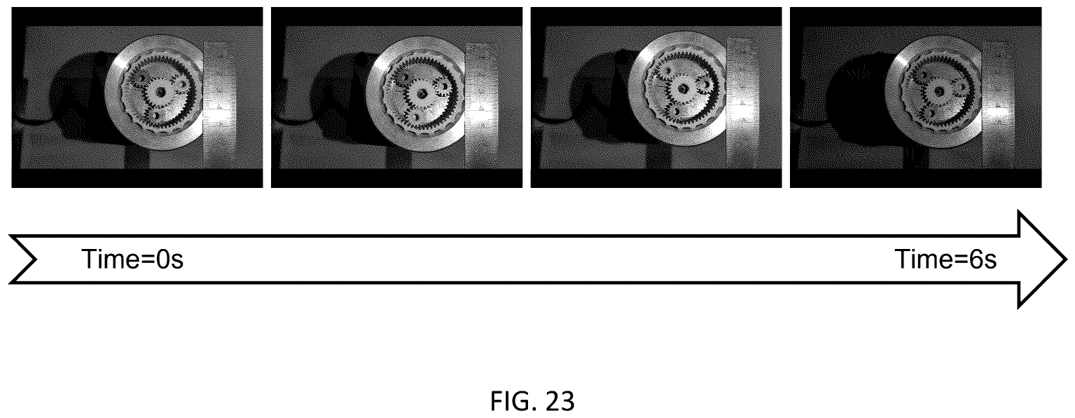

After the precursor is prepared using the above-mentioned additive manufacturing technology, the precursor is processed using precursor water cutting (PWC) processing and/or precursor water engraving (PWE) processing. As shown in FIG. 20, the processed precursor is then processed and converted into a high-temperature material, and the obtained high-temperature material is the ceramic material or glass material of the present invention. FIG. 21 shows the holes processed on the glass precursor through PWC processing. It can be seen that, generally speaking, PWC processing can achieve better processing resolution on the precursor than PLC processing. In FIG. 21, taking hole No. 4 as an example, its diameter is 1.13 mm and its roundness is 0.024. In this embodiment, PWC is used to process the ceramic precursor planetary gear system (as shown in FIGS. 22 and 23). FIG. 22 shows ceramic precursor planetary gear systems machined by PWC method. FIG. 23 shows running ceramic precursor planetary gear systems machined by PWC method.

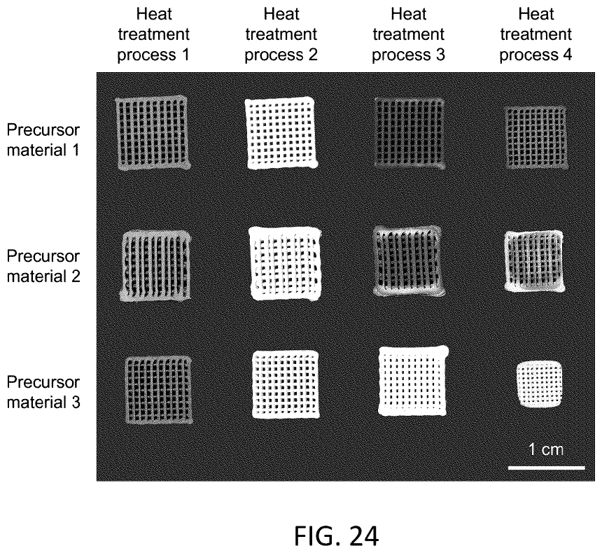

The processed precursor is subjected to heat processing in inert gas or vacuum conditions to undergo primary ceramization; and further subjecting to heat processing in air to undergo secondary ceramization. As the components and colours of the primary ceramized and secondary ceramized materials are different, printable and colour-tunable ceramic materials can therefore be obtained. FIG. 24 shows the printable and color-tunable ceramics developed in the present invention.

The artistic nature of ceramics and its ability to form complex structures and delicate features makes it suitable for creating unique pieces of art and decoration.

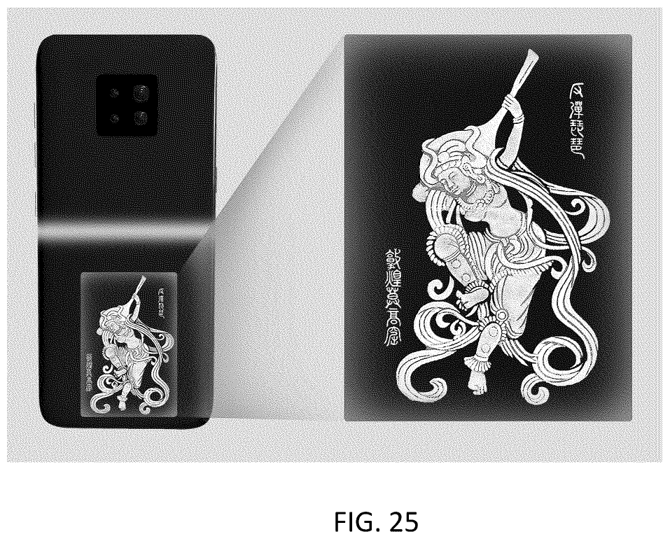

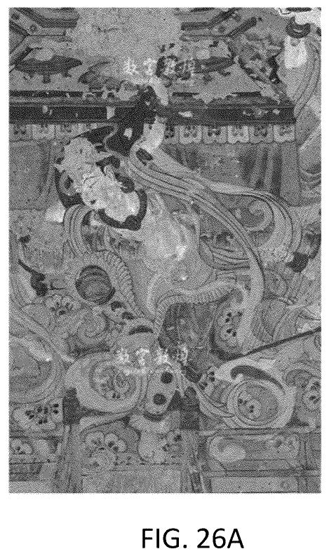

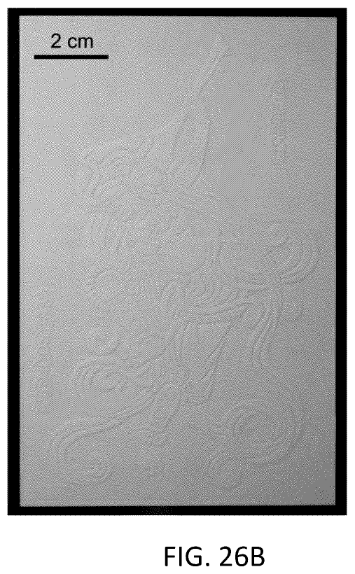

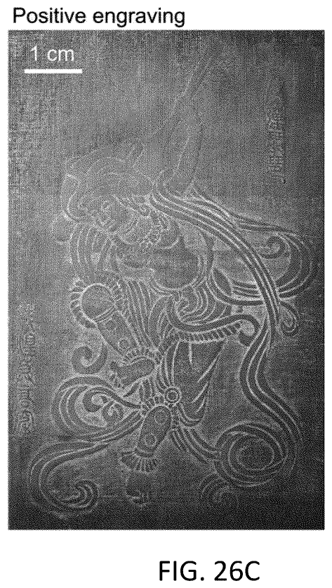

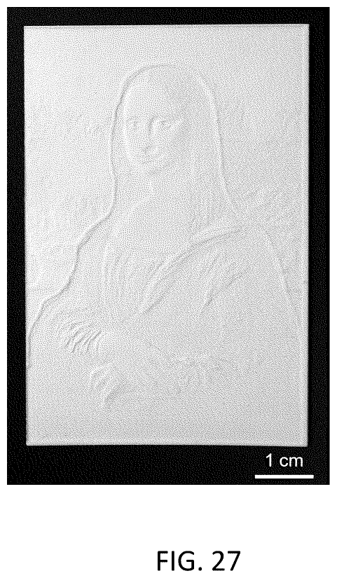

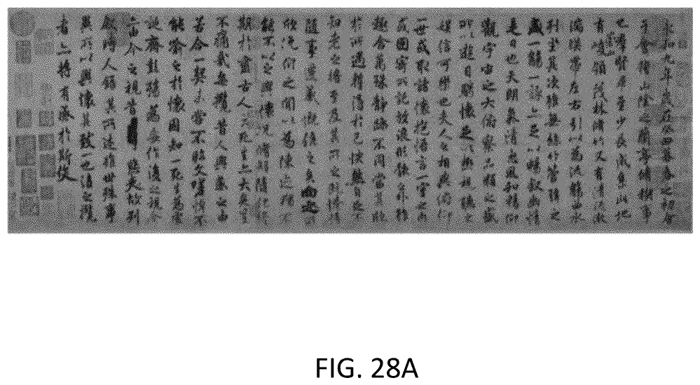

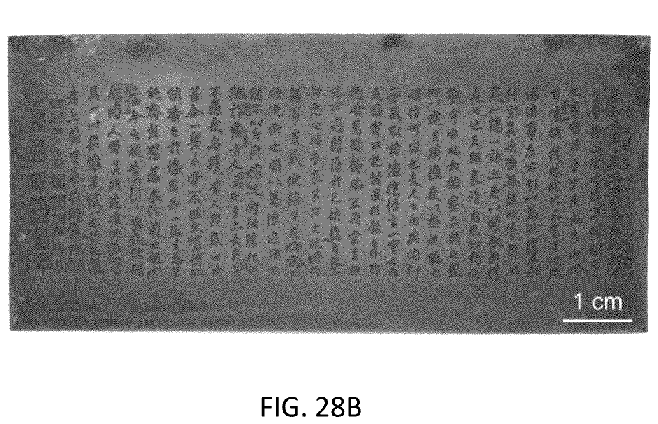

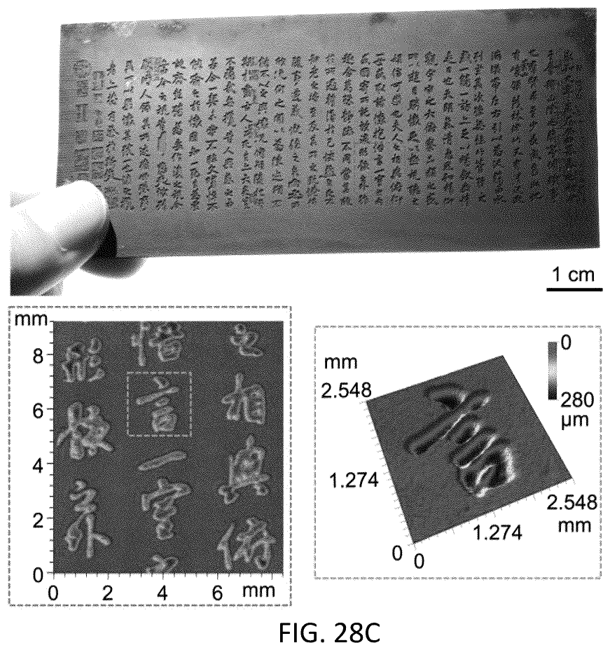

In an embodiment, a unique artistic and/or decorative ceramic mobile phone back plate is obtained, as shown in FIG. 25. By performing PLE on the precursor manufactured from the additive manufacturing technique mentioned above, complex 3D structural features can be introduced, which can possess artistic and/or decorative features. Positive engraving of famous artworks, for example “Flying Asparas” (FIG. 26) and “Mona Lisa” (FIGS. 27); and 3D negative engraving of famous calligraphy works (FIG. 28) is achieved. FIGS. 26A and 26C compares large-scale ceramic flat plates with delicate positive engraving of the mural character in Flying Apsaras in Dunhuang Murals with the original mural engravings. FIG. 26A is the original image of the mural characters; FIG. 26B shows the ceramic precursor and FIG. 26C shows the ceramic material. FIG. 27 shows large-scale ceramic precursor flat plates with delicate positive engraving of the “Mona Lisa”. FIGS. 28A to 28C shows large-scale ceramic flat plates with delicate negative engraving of Chinese traditional calligraphy characters in “Preface to the Poems Composed at the Orchid Pavilion” by Wang Xizhi in running script with the original calligraphy texts. FIG. 28A shows the original image of the calligraphy texts, FIG. 28B shows the ceramic material and FIG. 28C shows the 3D optical profile.

In an embodiment, the prepared ceramic material is partially receramized to obtain heterogeneous ceramics. FIG. 29 shows the process of partial receramization of a ceramic material to obtain heterogeneous ceramics. The ceramic material is obtained by preparing a precursor through the above 3D printing technology, processing by high-energy beam and transforming by aforementioned methods. The partial receramization in FIG. 29 is achieved through localized heat processing, which is conducted on the ceramic material under the cover of a heat processing mask produced by laser cutting for subsequent partial receramizing into heterogeneous ceramics. The localized heat processing is performed under inert gas or vacuum conditions, and the temperature is preferably at least 800° C.; more preferably in the range of 1100° C. to 1500° C. The obtained heterogeneous ceramics are suitable as ceramic artworks and/or decorations, or as ceramic components in 3C electronic devices with artistic and/or decorative properties.

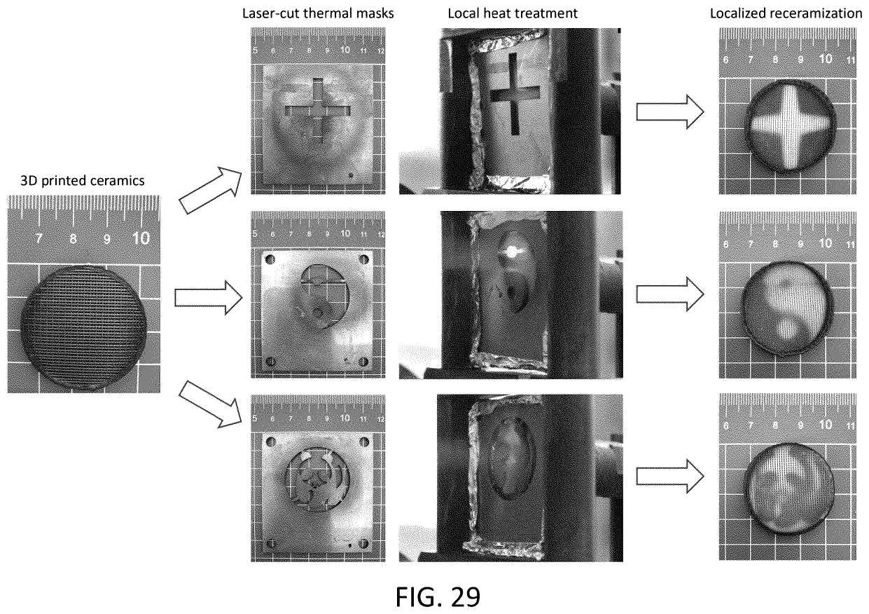

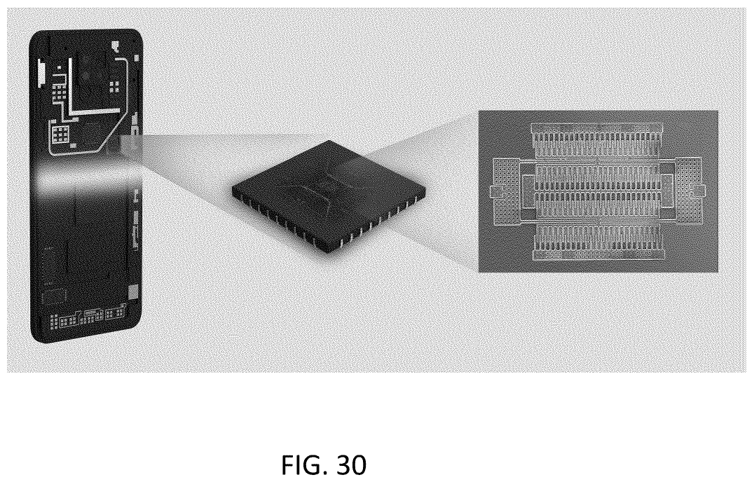

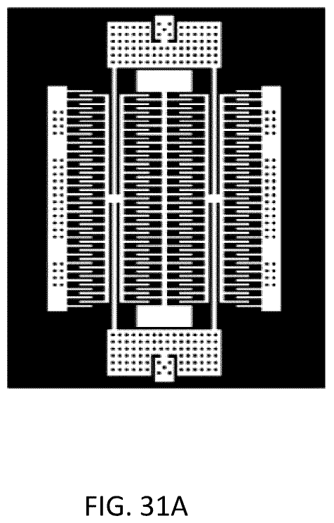

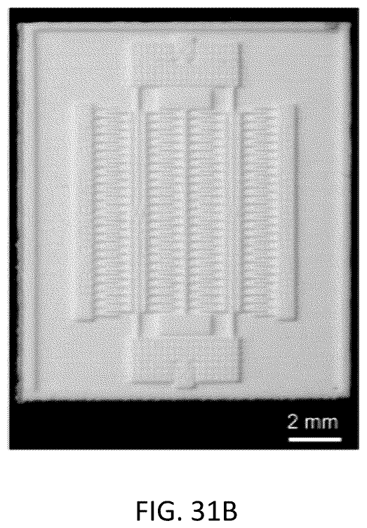

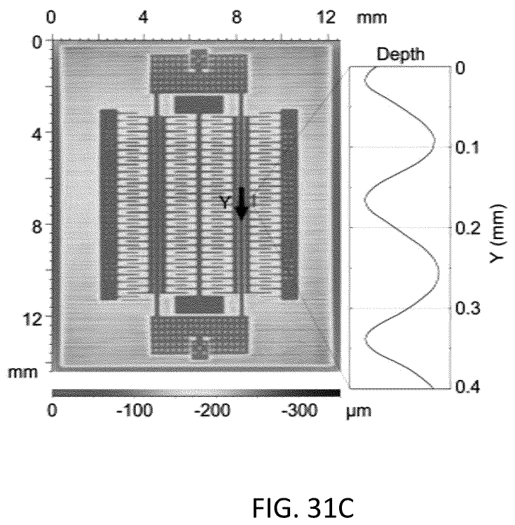

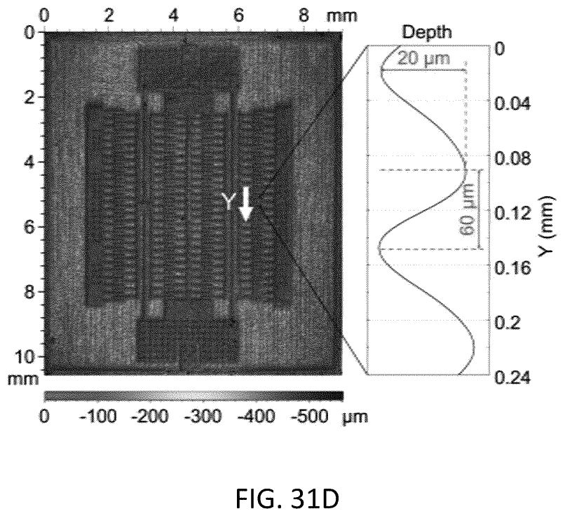

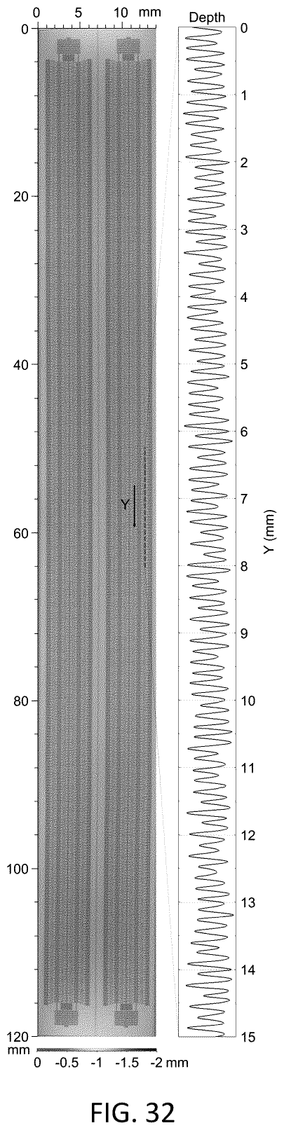

In an embodiment, the ceramic material produced is a ceramic microelectromechanical system (MEMS) in 3C electronic device. FIG. 30 shows the application of ceramic components in MEMS manufacturing in 3C electronic devices. This embodiment constructs a typical ceramic microelectromechanical system (MEMS) resonant strain sensor (length exceeds 10 mm, the depth and width of the tuning fork are approximately 20 μm and 60 μm respectively) and a large sensor (length exceeds 10 cm, 2812 pairs of electrodes, the depth and width of the tuning fork are 20 μm and 60 μm respectively) (shown in FIG. 31 and FIG. 32), the design is based on the double-ended tuning fork (DETF) topology. In electronic devices such as MEMS devices, the resonant frequency shift of DETF depends on the applied strain. FIG. 31 shows the structure of the laser-engraved ceramic microelectromechanical system, in which FIG. 31A shows the structural design of the MEMS structure, FIG. 31B shows the digital image of the ceramic precursor MEMS structure obtained using PLE, and FIG. 31C shows the ceramic precursor MEMS 3D optical profile of the structure with a resolution up to 80 μm, d shows the 3D optical profile of a ceramic MEMS structure obtained using PLE. FIG. 32 shows a typical ceramic microelectromechanical system (MEMS) resonant strain sensor (length over 10 cm, 2812 pairs of electrodes, tuning fork depth and width approximately 20 μm and 60 μm respectively), the design is based on a double-ended tuning fork (DETF) topology. Under a given applied strain, the large or cascaded MEMS resonant strain sensors printed in this embodiment are capable of exhibiting large frequency shifts. Using the PLE processing method can make the prepared strain sensor have better scalability, thereby improving the strain sensitivity. In addition, the ceramic MEMS resonant strain sensor of this embodiment is inherently resistant to high temperatures, temperature gradients, humidity, and other environmental effects, thereby minimizing the introduction of temperature or humidity noise into high-sensitivity measurement results. Therefore, high-resolution and large-scale ceramic MEMS resonant strain sensors fabricated using the ASM of the present invention exhibits enhanced sensitivity and reduced environmental interference, especially in adverse engineering environments.

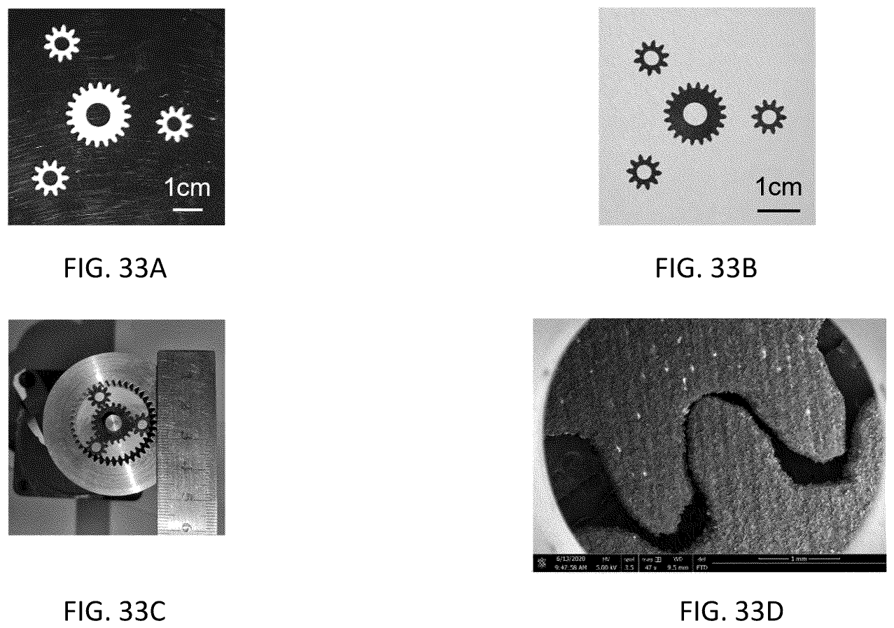

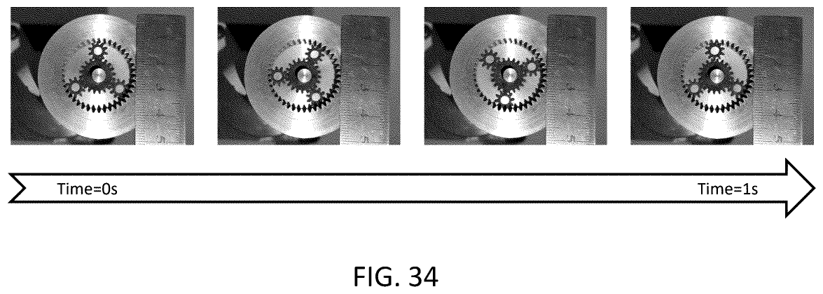

In an embodiment, a ceramic planetary gear system is obtained through PLC processing (as shown in FIGS. 33 and 34). This ceramic planetary gear system can be applied to ceramic microelectronic mechanical systems, which also shows the potential practical applications of ceramic MEMS in 3C electronic devices. FIGS. 33A to 33D shows planetary gear systems machined by PLC method. FIG. 33A shows the ceramic precursor; FIG. 33B shows the ceramic materials derived from the precursor; FIG. 33C shows the assembled planetary gear systems; and FIG. 33D is the SEM image. FIG. 34 shows running ceramic planetary gear systems machined by PLC method.

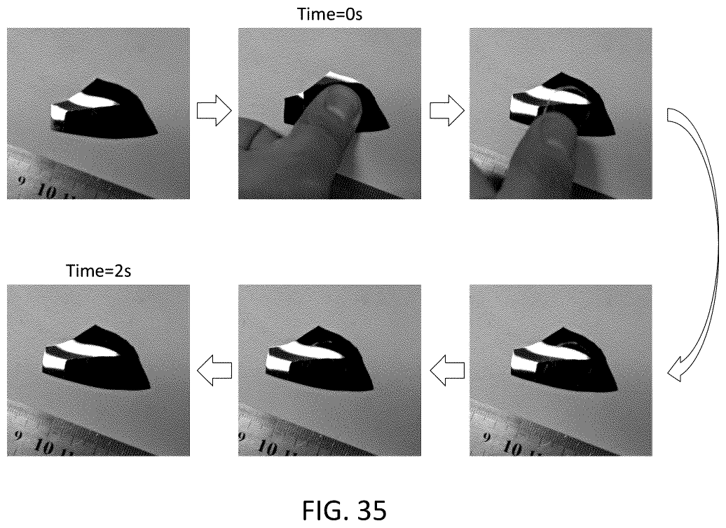

In an embodiment, the manufactured ceramic material is an anti-fingerprint polished ceramic plate having a ZrO₂—SiOC nanocrystalline-amorphous dual phase (NCADP) structure. As described above, after subjecting the processed precursor to induction heat processing under 1300° C., the precursor is transformed into a ZrO₂—SiOC nanocrystalline-amorphous dual phase (NCADP) ceramics, which can be applied as a ceramic mobile phone back plate or other components in 3C electronic devices. FIG. 35 demonstrates the anti-fingerprint property of the polished ceramic plate in the present invention.

As used herein, terms “approximately”, “basically”, “substantially”, and “about” are used for describing and explaining a small variation. When being used in combination with an event or circumstance, the term may refer to a case in which the event or circumstance occurs precisely, and a case in which the event or circumstance occurs approximately. As used herein with respect to a given value or range, the term “about” generally means in the range of ±10%, ±5%, ±1%, or ±0.5% of the given value or range. The range may be indicated herein as from one endpoint to another endpoint or between two endpoints. Unless otherwise specified, all the ranges disclosed in the present disclosure include endpoints. When reference is made to “substantially” the same numerical value or characteristic, the term may refer to a value within ±10%, ±5%, ±1%, or ±0.5% of the average of the values.

The foregoing description of the present invention has been provided for the purposes of illustration and description. It is not intended to be exhaustive or to limit the invention to the precise forms disclosed. Many modifications and variations will be apparent to the practitioner skilled in the art.

The embodiments were chosen and described in order to best explain the principles of the invention and its practical application, thereby enabling others skilled in the art to understand the invention for various embodiments and with various modifications that are suited to the particular use contemplated.

1. A method for manufacturing ceramic materials or glass materials, comprising:
preparing a precursor of a ceramic material or glass material;
processing the precursor by using a high-energy laser beam and/or water beam for engraving or cutting to obtain a processed precursor; and
transforming the processed precursor into a ceramic material or glass material by heat processing, mechanical processing or chemical processing, or any combination thereof;
wherein the precursor comprises:
a silicone-based and/or cellulose-based polymer; or
a polymer composite material, comprising a silicone-based and/or cellulose-based polymer matrix and a ceramic filler in the form of ceramic or glass powders, fibers, whiskers, plates or any combination thereof.

2. The method for manufacturing ceramic materials or glass materials of claim 1, wherein the silicone-based polymer or silicone-based polymer matrix is polydimethylsiloxane.

3. The method for manufacturing ceramic materials or glass materials of claim 1, wherein the ceramic filler is selected from ZrO₂, AlON, AlN, Al₂O₃, SiC or Si₃N₄, or any combination thereof.

4. The method for manufacturing ceramic materials or glass materials of claim 1, wherein:
the amount of silicone-based and/or cellulose-based polymer matrix is 10 wt % to 99 wt % of the polymer composite material; and
the amount of ceramic filler is 1 wt % to 90 wt % of the polymer composite material.

5. The method for manufacturing ceramic materials or glass materials of claim 1, wherein the precursor is obtained by additive manufacturing through 2D printing, 3D printing or 4D printing; and wherein the additive manufacturing is selected from one or more of material extrusion, film scraping, material jetting, photopolymerization or powder bed fusion.

6. The method for manufacturing ceramic materials or glass materials of claim 5, wherein the precursor is obtained by 3D printing or a combination of 3D printing and film scraping.

7. The method for manufacturing ceramic materials or glass materials of claim 1, further comprising performing heterogeneous engineering of the processed precursor prior to the transforming processed precursor into a ceramic material or glass material, wherein the heterogeneous engineering comprises subjecting the processed precursor to localized UV/ozone treatment.

8. The method for manufacturing ceramic materials or glass materials of claim 1, wherein the transforming the processed precursor into a ceramic material or glass material further comprises improving the machining accuracy of the ceramic material or glass material by linear shrinkage.

9. The method for manufacturing ceramic materials or glass materials of claim 1, further comprising subjecting the processed precursor to heat processing in inert gas or vacuum conditions to undergo primary ceramization; and further subjecting to heat processing in air to undergo secondary ceramization to obtain printable and colour-tunable ceramic material.

10. The method for manufacturing ceramic materials or glass materials of claim 1, wherein the processing the processed precursor is by laser engraving, and wherein the laser engraving comprises positive engraving and/or negative engraving for forming three-dimensional decorative structural profile with different depths.

11. The method for manufacturing ceramic materials or glass materials of claim 10, further comprising subjecting the ceramic material to localized receramization to obtain a heterogeneous ceramic material, wherein the localized receramization comprises localized heat processing with a temperature of at least 800° C.

12. A ceramic or glass component of a 3C electronic device manufactured according to the method of claim 1.

13. The ceramic or glass component of a 3C electronic device of claim 12, wherein the component is a decorative ceramic component of an electronic device or a ceramic back plate of an electronic device with a camera hole, wherein the back plate is selected from a flat ceramic back plate, a curved ceramic back plate, a foldable ceramic back plate or a stiffener-added ceramic plate.

14. The ceramic back plate of an electronic device of claim 13, wherein the camera hole and internal surface texture of the ceramic back plate is achieved by laser cutting or laser engraving of the precursor of ceramic material.

15. The ceramic back plate of an electronic device of claim 13, wherein the camera hole is achieved through water cutting of the precursor of ceramic material.

16. The ceramic back plate of an electronic device of claim 13, wherein the foldable ceramic back plate is manufactured with soft/rigid hybrid ceramic precursor/material or glass precursor/material achieved by localized ceramization of precursor materials, multi-material printing/assembly or combinations thereof.

17. The ceramic back plate of an electronic device of claim 13, wherein the stiffener-added ceramic plate is manufactured with 3D printing technique, or a combination of 3D printing technique and film scraping technique.

18. The ceramic back plate of an electronic device of claim 13, wherein the colour of the border of the digital files for laser machining the ceramic back plate is be designed to gradually become lighter to achieve a 2.5 D arc edge.

19. The ceramic or glass component of a 3C electronic device of claim 12, wherein the component is an anti-fingerprint polished ceramic plate with ZrO₂—SiOC nanocrystalline amorphous dual-phase structures.

20. The ceramic or glass component of a 3C electronic device of claim 12, wherein the component is a resonant strain sensor or a gear system of a ceramic or glass microelectromechanical system including a resonant strain sensor or a gear system.
